(19) United States
(12) Patent Application Publication
(10) Pub. No.: US 2024/0250658 A1
(43) Pub. Date: Jul. 25, 2024

(54) ACOUSTIC WAVE DEVICE

(71) Applicant: Murata Manufacturing Co., Ltd., Nagaokakyo-shi (JP)

(72) Inventors: Takuro OKADA, Nagaokakyo-shi (JP); Kentaro NAKAMURA, Nagaokakyo-shi (JP); Takuya YABU, Nagaokakyo-shi (JP)

(21) Appl. No.: 18/530,298

(22) Filed: Dec. 6, 2023

(30) Foreign Application Priority Data
Jan. 25, 2023 (JP) 2023-009570

(51) Int. Cl. H03H 9/02; H03H 9/205

(52) U.S. Cl. CPC H03H 9/02228; H03H 9/02015; H03H 9/02086; H03H 9/205

(57) ABSTRACT

An acoustic wave device includes a piezoelectric substrate including a piezoelectric layer, and IDT electrodes on the piezoelectric substrate and including curved IDT electrodes. A direction in which a portion of the electrode finger with a curved shape in the curved IDT electrode is convex is an outer side direction. Acoustic wave resonators include first and second acoustic wave resonators including first and second curved IDT electrodes, respectively. The first and second acoustic wave resonators are connected without another acoustic wave resonator interposed therebetween. When one of the directions in which electrode fingers are arranged is a first direction and a direction opposite to the first direction is a second direction, the outer side direction in the first IDT electrode is the first direction, and the outer side direction of the second IDT electrode is the second direction.

### CROSS REFERENCE TO RELATED APPLICATIONS

This application claims the benefit of priority to Japanese Patent Application No. 2023-009570 filed on Jan. 25, 2023. The entire contents of this application are hereby incorporated herein by reference.

### BACKGROUND OF THE INVENTION

### 1. Field of the Invention

The present invention relates to an acoustic wave device including a plurality of acoustic wave resonators.

### 2. Description of the Related Art

In the related art, an acoustic wave device is widely used as a filter of a mobile phone or the like. Chinese Patent Application Publication No. 113676149 discloses an example of an acoustic wave device. In the acoustic wave device, an interdigital transducer (IDT) electrode is provided on a piezoelectric substrate. In the IDT electrode, shapes of a plurality of electrode fingers are arc shapes. More specifically, the shapes of the plurality of electrode fingers are shapes, respectively, corresponding to arcs in a plurality of concentric circles. In the acoustic wave device of Chinese Patent Application Publication No. 113676149, unwanted waves are reduced or prevented.

### SUMMARY OF THE INVENTION

The present inventors have discovered that harmonic wave distortion is likely to occur in a case where the plurality of electrode fingers are curved. As a result, there is a concern that electric characteristics of the acoustic wave device deteriorate.

Preferred embodiments of the present invention provide acoustic wave devices that each reduce or prevent harmonic wave distortion.

According to a broad aspect of a preferred embodiment of the present invention, an acoustic wave device includes a piezoelectric substrate including a piezoelectric layer, and a plurality of IDT electrodes provided on the piezoelectric substrate and each including a plurality of electrode fingers. The plurality of IDT electrodes include a plurality of curved IDT electrodes in which shapes of the plurality of electrode fingers in plan view are curved shapes, a direction in which a curved portion including a curved shape of an electrode finger in a curved IDT electrode is convex in directions in which the plurality of electrode fingers are arranged is an outer side direction of the curved portion, the plurality of IDT electrodes include a first IDT electrode and a second IDT electrode, and both the first IDT electrode and the second IDT electrode are the curved IDT electrodes, a plurality of acoustic wave resonators each including the IDT electrode are provided and include a first acoustic wave resonator including the first IDT electrode and a second acoustic wave resonator including the second IDT electrode, and the first acoustic wave resonator and the second acoustic wave resonator are connected without another acoustic wave resonator interposed therebetween, and when one of the directions in which the plurality of electrode fingers are arranged is a first direction and a direction opposite to the first direction is a second direction in the first IDT electrode and the second IDT electrode, the outer side direction in the first IDT electrode is the first direction, and the outer side direction of the second IDT electrode is the second direction.

According to another broad aspect of a preferred embodiment of the present invention, an acoustic wave device includes a piezoelectric substrate including a piezoelectric layer, and a plurality of IDT electrodes provided on the piezoelectric substrate and each including a plurality of electrode fingers. The plurality of IDT electrodes include a plurality of curved IDT electrodes in which shapes of the plurality of electrode fingers in plan view are curved shapes, the plurality of IDT electrodes include a first IDT electrode and a second IDT electrode, and both the first IDT electrode and the second IDT electrode are the curved IDT electrodes, a plurality of acoustic wave resonators each including the IDT electrode are provided and include a first acoustic wave resonator including the first IDT electrode and a second acoustic wave resonator including the second IDT electrode, and the first acoustic wave resonator and the second acoustic wave resonator are connected without another acoustic wave resonator interposed therebetween, and when one of directions in which the plurality of electrode fingers are arranged is a first direction and a direction opposite to the first direction is a second direction in the first IDT electrode and the second IDT electrode, a length of an electrode finger increases toward the first direction in the first IDT electrode, and a length of an electrode finger increases toward the second direction in the second IDT electrode.

According to still another broad aspect of a preferred embodiment of the present invention, an acoustic wave device includes a piezoelectric substrate including a piezoelectric layer, and a plurality of IDT electrodes provided on the piezoelectric substrate and each including a plurality of electrode fingers. The plurality of IDT electrodes include a plurality of curved IDT electrodes in which shapes of the plurality of electrode fingers in plan view are curved shapes, a direction in which a portion including a curved shape of an electrode finger in a curved IDT electrode is convex in directions in which the plurality of electrode fingers are arranged is an outer side direction of the portion including the curved shape, the plurality of IDT electrodes include a first IDT electrode and a second IDT electrode, and both the first IDT electrode and the second IDT electrode are the curved IDT electrodes, when one of the directions in which the plurality of electrode fingers are arranged is a first direction and a direction opposite to the first direction is a second direction in the first IDT electrode and the second IDT electrode, the first IDT electrode includes at least one first region where the outer side direction is the first direction and at least one second region where the outer side direction is the second direction, and the second IDT electrode includes at least a region where the outer side direction is the second direction, a plurality of acoustic wave resonators each including the IDT electrode are provided and include a first acoustic wave resonator including the first IDT electrode and a second acoustic wave resonator including the second IDT electrode, and the first acoustic wave resonator and the second acoustic wave resonator are connected without another acoustic wave resonator interposed therebetween, a total area of the first region is larger than a total area of the second region in the first IDT electrode, and a total area of the region where the outer side direction is the second direction is larger than a total area of the region where the outer side direction is the first direction in the second IDT electrode.

According to still another broad aspect of a preferred embodiment of the present invention, an acoustic wave device includes a piezoelectric substrate including a piezoelectric layer, and a plurality of IDT electrodes provided on the piezoelectric substrate and each including a plurality of electrode fingers. The plurality of IDT electrodes include a plurality of curved IDT electrodes in which shapes of the plurality of electrode fingers in plan view are curved shapes, a direction in which a curved portion including a curved shape of an electrode finger in a curved IDT electrode is convex in directions in which the plurality of electrode fingers are arranged is an outer side direction of the curved portion, the plurality of IDT electrodes include a first IDT electrode and a second IDT electrode, and both the first IDT electrode and the second IDT electrode are the curved IDT electrodes, when one of the directions in which the plurality of electrode fingers are arranged is a first direction and a direction opposite to the first direction is a second direction in the first IDT electrode and the second IDT electrode, the first IDT electrode includes at least one first region where the outer side direction is the first direction and at least one second region where the outer side direction is the second direction, and the second IDT electrode includes at least a region where the outer side direction is the second direction, a plurality of acoustic wave resonators each including the IDT electrode are provided and include a first acoustic wave resonator including the first IDT electrode and a second acoustic wave resonator including the second IDT electrode, and the first acoustic wave resonator and the second acoustic wave resonator are connected without another acoustic wave resonator interposed therebetween, a total area of the first region is larger than a total area of the second region in the first IDT electrode, a length of an electrode finger increases toward one of the first direction and the second direction in the first IDT electrode, and a length of an electrode finger increases toward another of the first direction and the second direction in the second IDT electrode.

According to the acoustic wave devices according to preferred embodiments of the present invention, harmonic wave distortion is reduced or prevented.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a schematic plan view of an acoustic wave device according to a first preferred embodiment of the present invention.

FIG. 2 is a schematic cross-sectional view taken along line I-I in FIG. 1.

FIG. 3 is a schematic plan view for describing a configuration of a first IDT electrode according to a first preferred embodiment of the present invention.

FIG. 4 is a schematic plan view of an acoustic wave resonator of a comparative example.

FIG. 5 is a diagram illustrating levels of second-harmonic wave distortion according to the first preferred embodiment of the present invention and the comparative example.

FIG. 6 is a schematic plan view for describing a flow of a secondary distorted current in a straight IDT electrode.

FIG. 7 is a schematic plan view for describing a flow of secondary distorted currents in two curved IDT electrodes disposed as in the first preferred embodiment of the present invention.

FIG. 8 is a schematic plan view of an acoustic wave device according to a modification example of the first preferred embodiment of the present invention.

FIG. 9 is a schematic plan view for describing a flow of secondary distorted currents in two curved IDT electrodes disposed as in the modification example of the first preferred embodiment of the present invention.

FIG. 10 is a schematic plan view for describing a configuration of a first acoustic wave resonator according to a second preferred embodiment of the present invention.

FIG. 11 is a schematic plan view of an acoustic wave device according to the second preferred embodiment of the present invention.

FIG. 12 is a diagram illustrating a relationship between an absolute value |θ_{c}| of an angle θ_{c} and a duty ratio of a first IDT electrode according to the second preferred embodiment of the present invention.

FIG. 13 is a schematic plan view for describing a configuration of a first IDT electrode according to a first modification example of the second preferred embodiment of the present invention.

FIG. 14 is a schematic plan view of a first IDT electrode according to a second modification example of the second preferred embodiment of the present invention.

FIG. 15 is a schematic plan view for describing a configuration of the first IDT electrode according to the second modification example of the second preferred embodiment of the present invention.

FIG. 16 is a schematic plan view of an acoustic wave device according to a third modification example of the second preferred embodiment of the present invention.

FIG. 17 is a schematic plan view of an acoustic wave device according to a fourth modification example of the second preferred embodiment of the present invention.

FIG. 18 is a schematic plan view of an acoustic wave device according to a fifth modification example of the second preferred embodiment of the present invention.

FIG. 19 is a schematic plan view of an acoustic wave device according to a sixth modification example of the second preferred embodiment of the present invention.

FIG. 20 is a schematic plan view of an acoustic wave device according to a third preferred embodiment of the present invention.

FIG. 21 is a schematic plan view of an acoustic wave device according to a fourth preferred embodiment of the present invention.

FIG. 22 is a schematic plan view for describing a configuration of a first IDT electrode according to the fourth preferred embodiment of the present invention.

FIG. 23 is a schematic plan view of an acoustic wave device according to a modification example of the fourth preferred embodiment of the present invention.

FIG. 24 is a schematic elevational cross-sectional view of an acoustic wave device according to a fifth preferred embodiment of the present invention.

FIG. 25 is a schematic elevational cross-sectional view of an acoustic wave device according to a first modification example of the fifth preferred embodiment of the present invention.

FIG. 26 is a schematic elevational cross-sectional view of an acoustic wave device according to a second modification example of the fifth preferred embodiment of the present invention.

FIG. 27 is a schematic elevational cross-sectional view of an acoustic wave device according to a sixth preferred embodiment of the present invention.

FIG. 28 is a schematic elevational cross-sectional view of an acoustic wave device according to a seventh preferred embodiment of the present invention.

FIG. 29 is a schematic elevational cross-sectional view of an acoustic wave device according to a first modification example of the seventh preferred embodiment of the present invention.

FIG. 30 is a schematic elevational cross-sectional view of an acoustic wave device according to a second modification example of the seventh preferred embodiment of the present invention.

FIG. 31 is a schematic elevational cross-sectional view of an acoustic wave device according to a third modification example of the seventh preferred embodiment of the present invention.

FIG. 32 is a circuit diagram of an acoustic wave device according to an eighth preferred embodiment of the present invention.

FIG. 33 is a schematic plan view illustrating a plurality of parallel arm resonators and a plurality of series arm resonators according to the eighth preferred embodiment of the present invention.

FIG. 34 is a schematic plan view illustrating a parallel arm resonator and a series arm resonator according to a first modification example of the eighth preferred embodiment of the present invention.

FIG. 35 is a schematic plan view illustrating a parallel arm resonator and a series arm resonator according to a second modification example of the eighth preferred embodiment of the present invention.

FIG. 36 is a circuit diagram of an acoustic wave device according to a ninth preferred embodiment of the present invention.

FIG. 37 is a schematic plan view illustrating a plurality of series arm resonators according to the ninth preferred embodiment of the present invention.

FIG. 38 is a schematic plan view illustrating a plurality of series arm resonators according to a modification example of the ninth preferred embodiment of the present invention.

FIG. 39 is a schematic plan view illustrating a parallel arm resonator and a plurality of series arm resonators according to a tenth preferred embodiment of the present invention.

FIG. 40 is a schematic plan view illustrating a parallel arm resonator and a plurality of series arm resonators according to an eleventh preferred embodiment of the present invention.

FIG. 41 is a circuit diagram of an acoustic wave device according to a twelfth preferred embodiment of the present invention.

FIG. 42 is a schematic plan view illustrating a plurality of parallel arm resonators and a plurality of series arm resonators according to the twelfth preferred embodiment of the present invention.

### DETAILED DESCRIPTION OF THE PREFERRED EMBODIMENTS

Hereinafter, the present invention will be clarified by describing specific preferred embodiments of the present invention with reference to the drawings.

Note that, each preferred embodiment described in the present specification is an example, and partial replacement or combination of configurations can be made between different preferred embodiments.

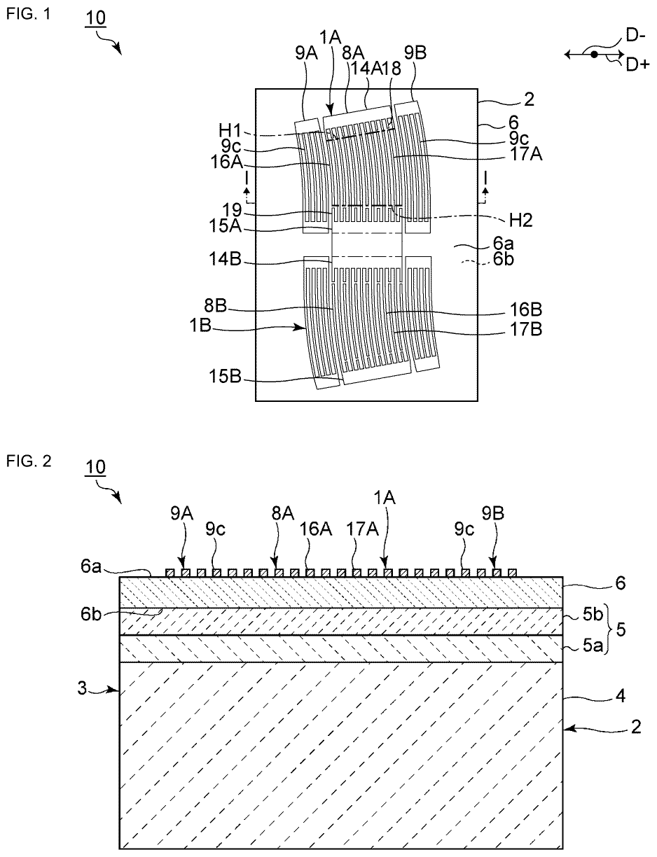

FIG. 1 is a schematic plan view of an acoustic wave device according to a first preferred embodiment of the present invention. FIG. 2 is a schematic cross-sectional view taken along line I-I in FIG. 1. Note that, in FIG. 1, a boundary between a busbar and a wiring, which will be described later, is indicated by a dashed dotted line. The same applies to schematic plan views other than FIG. 1.

An acoustic wave device 10 illustrated in FIG. 1 is used as a portion of a filter device. The acoustic wave device 10 includes a first acoustic wave resonator 1A and a second acoustic wave resonator 1B. However, an acoustic wave device according to a preferred embodiment of the present invention may be a filter device. It is sufficient that an acoustic wave device according to a preferred embodiment of the present invention includes at least two acoustic wave resonators.

As illustrated in FIG. 2, the acoustic wave device 10 includes a piezoelectric substrate 2. The piezoelectric substrate 2 is a laminated substrate including a piezoelectric layer 6. In other words, the piezoelectric substrate 2 is a substrate having piezoelectricity. Specifically, the piezoelectric substrate 2 includes a support 3 and the piezoelectric layer 6. More specifically, the support 3 includes a support substrate 4 and an intermediate layer 5. The intermediate layer 5 includes a first layer 5a and a second layer 5b. The first layer 5a is provided on the support substrate 4. The second layer 5b is provided on the first layer 5a. The piezoelectric layer 6 is provided on the second layer 5b. Note that, a layer configuration of the piezoelectric substrate 2 is not limited to the above configuration. For example, the intermediate layer 5 may be a single dielectric layer. Alternatively, the piezoelectric substrate 2 may be a substrate including only the piezoelectric layer 6.

In the present preferred embodiment, silicon is preferably used as a material of the support substrate 4, for example. Silicon nitride is used as a material of the first layer 5a. Silicon oxide is used as a material of the second layer 5b. Rotated Y-cut X-propagation lithium tantalate is used as the material of the piezoelectric layer 6. However, the material of each layer of the piezoelectric substrate 2 is not limited to the above material.

The piezoelectric layer 6 includes a first primary surface 6a and a second primary surface 6b. The first primary surface 6a and the second primary surface 6b face each other. The second primary surface 6b out of the first primary surface 6a and the second primary surface 6b is positioned close to the support substrate 4. A first IDT electrode 8A is provided on the first primary surface 6a of the piezoelectric layer 6. As a result, the first acoustic wave resonator 1A is provided.

Referring back to FIG. 1, the first IDT electrode 8A includes a pair of busbars. The pair of busbars is specifically a first busbar 14A and a second busbar 15A. The first busbar 14A and the second busbar 15A face each other. One end portions of a plurality of first electrode fingers 16A are connected to the first busbar 14A. One end portions of a plurality of second electrode fingers 17A are connected to the second busbar 15A. Note that, each of the plurality of first electrode fingers 16A and the plurality of second electrode fingers 17A includes a base end portion and a distal end portion. The base end portion of the first electrode finger 16A is a portion connected to the first busbar 14A. The base end portion of the second electrode finger 17A is a portion connected to the second busbar 15A. The plurality of first electrode fingers 16A and the plurality of second electrode fingers 17A are interdigitated with each other. The first electrode fingers 16A and the second electrode fingers 17A are connected to potentials different from each other.

Hereinafter, the first electrode finger 16A and the second electrode finger 17A may be simply described as an electrode finger. The first busbar 14A and the second busbar 15A may be simply described as a busbar.

A virtual line formed by connecting the distal end portions of the plurality of second electrode fingers 17A of the first IDT electrode 8A is defined as a first envelope H1, and a virtual line formed by connecting the distal end portions of the plurality of first electrode fingers 16A is defined as a second envelope H2. A region between the first envelope H1 and the second envelope H2 is the intersection region F of the first IDT electrode 8A. More specifically, a region surrounded by an electrode finger at one end portion and an electrode finger at the other end portion in a direction in which the plurality of electrode fingers are arranged among the plurality of electrode fingers, the first envelope H1, and the second envelope H2 is the intersection region F. Thus, the first envelope H1 corresponds to an end edge portion of the intersection region F close to the first busbar 14A. The second envelope H2 corresponds to an end edge portion of the intersection region F close to the second busbar 15A. An AC voltage is applied to the first IDT electrode 8A, and thus, an acoustic wave is excited in the intersection region F.

In the first IDT electrode 8A in the acoustic wave device 10, an electrode finger pitch is constant. The electrode finger pitch of the IDT electrode is a distance between centers of the first electrode finger 16A and the second electrode finger 17A that are adjacent to each other. When the electrode finger pitch is defined as p and a wavelength defined by the electrode finger pitch p is defined as λ, the wavelength λ is λ=2p, for example.

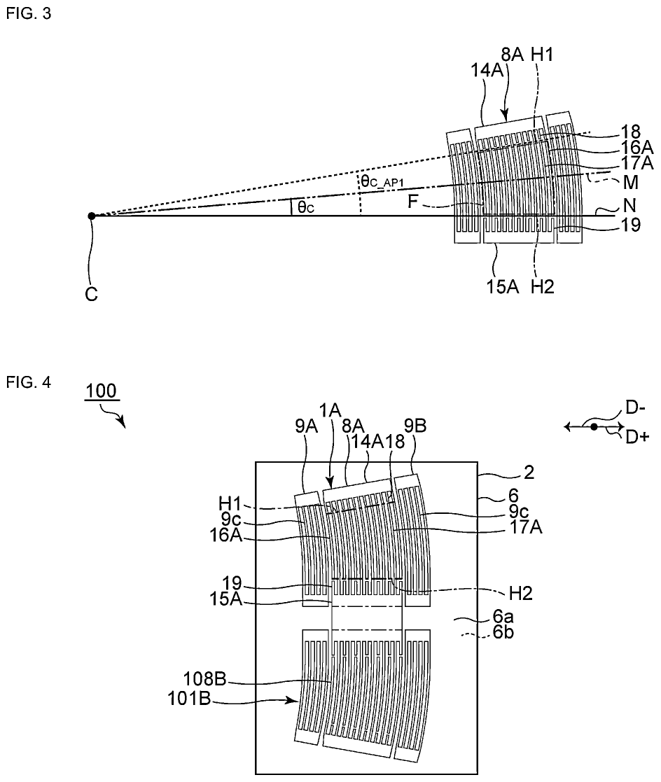

FIG. 3 is a schematic plan view for describing a configuration of the first IDT electrode according to the first preferred embodiment.

The first IDT electrode 8A is a curved IDT electrode according to the present invention. In the curved IDT electrode, shapes of the plurality of electrode fingers in plan view are curved shapes. In the present specification, plan view means a view from a direction corresponding to an upper side in FIG. 2. In FIG. 2, for example, out of a side close to the support substrate 4 and a side close to the piezoelectric layer 6, the side close to the piezoelectric layer 6 is the upper side.

As illustrated in FIG. 3, in the first IDT electrode 8A, specifically, the shapes of the plurality of electrode fingers in plan view include shapes corresponding to arcs of a plurality of concentric circles. Centers of circles including arcs in the shapes of the plurality of electrode fingers coincide with each other. The center is defined as the fixed point C. Note that, in the present preferred embodiment, the shapes of the plurality of first electrode fingers 16A in plan view are arc shapes. On the other hand, the shapes of the plurality of second electrode fingers 17A in plan view include arc shapes and straight line shapes. Specifically, in a region between the second envelope H2 and the second busbar 15A, the shapes of the plurality of second electrode fingers 17A have straight shapes in plan view. In a region other than the region, the shapes of the plurality of second electrode fingers 17A in plan view are arc shapes.

Note that, the shapes of the plurality of electrode fingers of the first IDT electrode 8A are not limited to the above shapes. It is sufficient that the shapes of the plurality of electrode fingers of the first IDT electrode 8A in plan view include curved shapes in the intersection region F. The shapes of the plurality of electrode fingers of the first IDT electrode 8A in plan view may be, for example, an elliptical arc shape, or may be curved shapes other than the arc shape and the elliptical arc shape.

A direction in which a portion having the curved shape of the electrode finger is convex in directions in which the plurality of electrode fingers are arranged is an outer side direction of the portion having the curved shape. A direction opposite to the outer side direction is an inner side direction. Then, when one among the directions in which the plurality of electrode fingers are arranged is defined as a first direction D+, a direction on a right side in FIG. 1 is the first direction D+ in the present preferred embodiment. When a direction opposite to the first direction D+ is defined as a second direction D−, directions on a left side in FIG. 1 are the second direction D−. In the first acoustic wave resonator 1A, outer side directions of the plurality of electrode fingers of the first IDT electrode 8A are directions on the right side in FIG. 1. Thus, the outer side directions of the plurality of electrode fingers of the first IDT electrode 8A are the first direction D+.

In the first IDT electrode 8A, a distance between the first envelope H1 and the second envelope H2 in a direction orthogonal to the first direction D+ increases in length toward the first direction D+. Then, in the first IDT electrode 8A, a length of the electrode finger increases toward the first direction D+.

In the present preferred embodiment, the intersection region F includes only one curved region. In the present specification, the curved region means a region where the shapes of the plurality of electrode fingers are curved in plan view. In the curved region of the first IDT electrode 8A of the acoustic wave device 10, the shapes of the plurality of first electrode fingers 16A and the plurality of second electrode fingers 17A in plan view are single arc shapes. Note that, for example, in the curved region, the shape of each electrode finger in plan view may be a single elliptical arc shape. In the curved region, the outer side directions of all the electrode fingers in plan view coincide with each other. However, in various preferred embodiments of the present invention, the intersection region F may include a plurality of curved regions.

IDT electrodes other than the first IDT electrode 8A are also provided on the piezoelectric substrate 2. Specifically, in the present preferred embodiment, as illustrated in FIG. 1, a second IDT electrode 8B is provided on the piezoelectric substrate 2. As a result, the second acoustic wave resonator 1B is provided. The second IDT electrode 8B is a curved IDT electrode. Outer side directions of the plurality of electrode fingers of the second IDT electrode 8B are directions on the left side in FIG. 1. Thus, the outer side directions of the plurality of electrode fingers of the second IDT electrode 8B are the second direction D−. In the second IDT electrode 8B, the length of the electrode finger increases toward the second direction D−.

Note that, in the present preferred embodiment, the shapes of the first IDT electrode 8A and the second IDT electrode 8B are the same. However, on the piezoelectric substrate 2, the disposition of the second IDT electrode 8B corresponds to a disposition in which the first IDT electrode 8A is rotated by 180°. Thus, the outer side directions of the plurality of electrode fingers in the first IDT electrode 8A and the outer side directions of the plurality of electrode fingers in the second IDT electrode 8B are different from each other.

Specifically, the second IDT electrode 8B includes a first busbar 14B, a second busbar 15B, a plurality of first electrode fingers 16B, and a plurality of second electrode fingers 17B. Shapes of the plurality of first electrode fingers 16B in the second IDT electrode 8B are shapes similar to the shapes of the plurality of second electrode fingers 17A in the first IDT electrode 8A. The shapes of the plurality of second electrode fingers 17B in the second IDT electrode 8B are similar to the shapes of the plurality of first electrode fingers 16A in the first IDT electrode 8A. Note that, for example, the shape of the first IDT electrode 8A and the shape of the second IDT electrode 8B may be in a line symmetrical relationship.

As described above, in the first IDT electrode 8A and the second IDT electrode 8B in the first acoustic wave resonator 1A and the second acoustic wave resonator 1B, the shapes of the plurality of electrode fingers in plan view are curved shapes. Thus, unwanted waves of the first acoustic wave resonator 1A and the second acoustic wave resonator 1B can be dispersed, and the unwanted waves can be reduced or prevented.

As described above, a Y-cut X-propagation piezoelectric material is used as the material of the piezoelectric layer 6. In the present preferred embodiment, the first direction D+ is a positive direction in an X-propagation direction. The second direction D− is a negative direction in the X-propagation direction. However, a relationship between the first direction D+ and the second direction D− and the X-propagation direction is not limited to the above. For example, it is sufficient that the first direction D+ be one of the positive direction and the negative direction in the X-propagation direction, and the second direction D− be the other of the positive direction and the negative direction in the X-propagation direction. Alternatively, the first direction D+ and the second direction D− may intersect the X-propagation direction.

The first acoustic wave resonator 1A includes a pair of reflector 9A and reflector 9B. Specifically, the reflector 9A and the reflector 9B are provided on the first primary surface 6a of the piezoelectric layer 6. The reflector 9A and the reflector 9B face each other with the first IDT electrode 8A interposed therebetween in the directions in which the plurality of electrode fingers of the first IDT electrode 8A are arranged.

The reflector 9A and the reflector 9B each include a plurality of reflector electrode fingers 9c. More specifically, the shapes of the plurality of electrode fingers of the first IDT electrode 8A and the plurality of reflector electrode fingers 9c of each reflector in plan view are shapes corresponding to arcs of a plurality of concentric circles. Thus, centers of circles including arcs in the shapes of the plurality of reflector electrode fingers 9c are the fixed point C. However, the shapes of the plurality of reflector electrode fingers 9c are not limited to the above shapes.

A feature of the present preferred embodiment is that the first acoustic wave resonator 1A and the second acoustic wave resonator 1B are connected to each other without another acoustic wave resonator interposed therebetween. The outer side direction of the first IDT electrode 8A is the first direction D+, and the outer side direction of the second IDT electrode 8B is the second direction D−. Thus, harmonic wave distortion can be reduced or prevented. This effect will be specifically described below by comparing the present preferred embodiment and a comparative example.

As illustrated in FIG. 4, the comparative example is different from the first preferred embodiment in that the outer side directions of the plurality of electrode fingers in the first IDT electrode 8A are the same as the outer side directions of the plurality of electrode fingers in the second IDT electrode 108B. The acoustic wave device 10 having the configuration of the first preferred embodiment and an acoustic wave device 100 of the comparative example are prepared, and a level of second-harmonic wave distortion (2HD) of each acoustic wave device was measured. Specifically, a signal at a resonant frequency of each acoustic wave device was input, and a level of second-harmonic waves was measured near a frequency twice the resonant frequency. Example design parameters of the first acoustic wave resonator 1A in the acoustic wave device 10 of the first preferred embodiment according to the comparison are as follows.

Number of pairs of electrode fingers of first IDT electrode 8A: 80 pairs

Angle of corner formed by first envelope H1 and second envelope H2: 9°

Duty ratio at portion through which first envelope H1 passes: 0.5

Wavelength λ: 2.08 μm

Area of intersection region F: 5516 μm²

Example design parameters of the second acoustic wave resonator 1B in the acoustic wave device 10 of the first preferred embodiment and the first acoustic wave resonator 1A and a second acoustic wave resonator 101B in the acoustic wave device 100 of the comparative example are similar to the above design parameters. The resonant frequency of each acoustic wave resonator was set to 1868 MHz, for example.

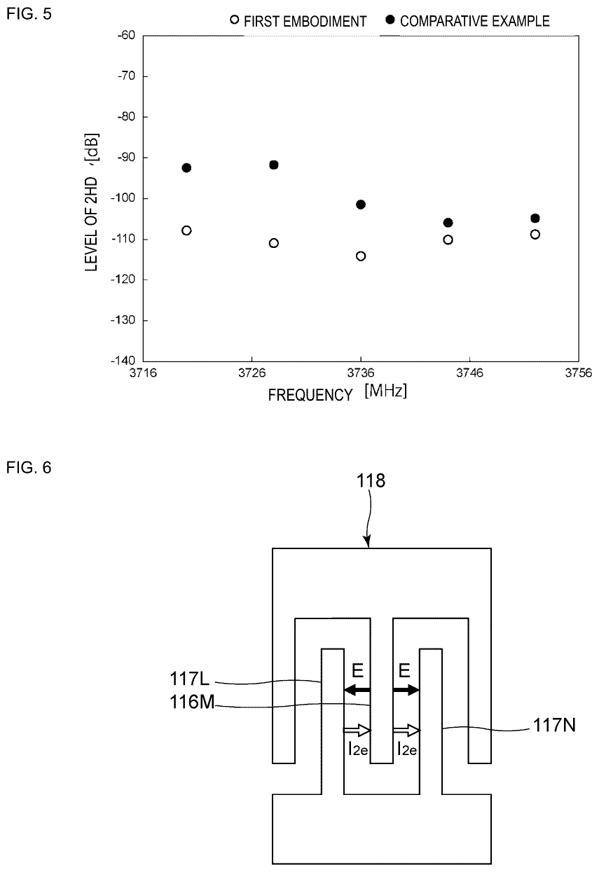

FIG. 5 is a diagram illustrating levels of second-harmonic wave distortion in the first preferred embodiment and the comparative example. In FIG. 5, a range of 2Fr±20 [MHz] is illustrated when the resonant frequency is Fr.

As illustrated in FIG. 5, it can be seen that the second-harmonic wave distortion can be reduced or prevented more than in the comparative example near 2Fr±20 [MHz] in the first preferred embodiment. The reason will be described below.

Referring back to FIG. 1, in the acoustic wave device 10, the first IDT electrode 8A and the second IDT electrode 8B in the first acoustic wave resonator 1A and the second acoustic wave resonator 1B are the curved IDT electrodes. As a result, the unwanted waves can be reduced or prevented in the acoustic wave device 10. However, the present inventors have discovered that harmonic wave distortion is more likely to occur in a case where the IDT electrode is the curved IDT electrode than in a case where the shapes of the electrode fingers of the IDT electrode are the straight shapes in plan view. On the other hand, in the first preferred embodiment, the first acoustic wave resonator 1A and the second acoustic wave resonator 1B are directly connected to each other without another acoustic wave resonator interposed therebetween, and the outer side direction of the first IDT electrode 8A and the outer side direction of the second IDT electrode 8B are opposite directions to each other. Thus, the second-harmonic wave distortion is reduced or prevented. The details will be described below.

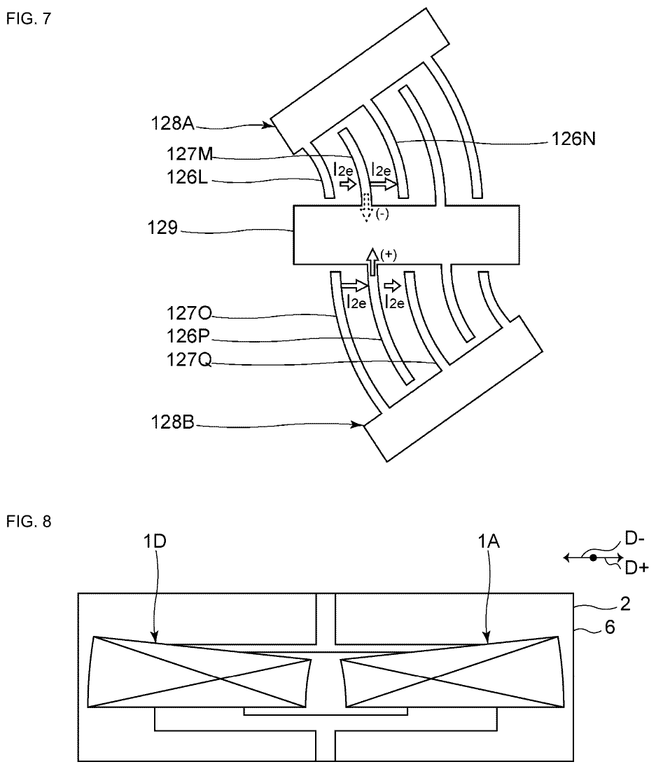

FIG. 6 is a schematic plan view for describing a flow of a secondary distorted current in the straight IDT electrode. FIG. 7 is a schematic plan view for describing flows of secondary distorted currents in two curved IDT electrodes disposed as in the first preferred embodiment. Note that, in the present specification, the straight IDT electrode means an IDT electrode whose shape of the electrode finger is straight in plan view.

A plurality of electrode fingers of a straight IDT electrode 118 illustrated in FIG. 6 include a first electrode finger 116M, a second electrode finger 117L, and a second electrode finger 117N. From a left side in FIG. 6, the second electrode finger 117L, the first electrode finger 116M, and the second electrode finger 117N are sequentially arranged in this order. In FIG. 6, an example in which when a voltage is applied to the straight IDT electrode 118, a potential of the first electrode finger 116M is higher than potentials of the second electrode finger 117L and the second electrode finger 117N is illustrated. The first electrode finger 116M is sandwiched between the second electrode finger 117L and the second electrode finger 117N. Thus, directions of an electric field E with the first electrode finger 116M as a reference are two directions.

Here, mechanical distortion and electric distortion contribute to the second-harmonic wave distortion of the harmonic wave distortion. The electric distortion is caused by a secondary distorted current I₂ₑ. The secondary distorted current I₂ₑ is proportional to the square of the electric field E. Thus, the secondary distorted current I₂ₑ flows in a constant direction regardless of the direction of the electric field E. For example, a secondary distorted current I₂ₑ flows from the second electrode finger 117L into the first electrode finger 116M. Simultaneously, a secondary distorted current I₂ₑ flows out from the first electrode finger 116M to the second electrode finger 117N.

A magnitude of the secondary distorted current I₂ₑ depends on the length of the electrode finger. Then, in the straight IDT electrode 118, lengths of the plurality of electrode fingers are the same. Thus, a magnitude of the secondary distorted current I₂ₑ flowing into the first electrode finger 116M is the same as a magnitude of the secondary distorted current I₂ₑ flowing out from the first electrode finger 116M. Thus, mismatching is unlikely to occur between the secondary distorted current I₂ₑ flowing into the first electrode finger 116M and the secondary distorted current I₂ₑ flowing out from the first electrode finger 116M. In other words, the secondary distorted current I₂ₑ is canceled in the first electrode finger 116M. As a result, an outflow of a current caused by the secondary distorted current I₂ₑ is unlikely to occur to an outside of the straight IDT electrode 118. The same applies to other electrode fingers. Thus, a signal of second-harmonic wave distortion is unlikely to be output from the straight IDT electrode 118.

On the other hand, the outflow of a current caused by the secondary distorted current I₂ₑ is likely to occur from the curved IDT electrode. That is, a signal of second-harmonic wave distortion is likely to be output from the curved IDT electrode.

More specifically, in a curved IDT electrode 128A illustrated in FIG. 7, a magnitude of the secondary distorted current I₂ₑ flowing between the electrode fingers is not constant. Specifically, in the curved IDT electrode 128A, a length of the electrode finger increases toward a right side in FIG. 7. For example, from a left side in FIG. 7, a first electrode finger 126L, a second electrode finger 127M, and a first electrode finger 126N are sequentially arranged in this order. Then, a length of the second electrode finger 127M is longer than a length of the first electrode finger 126L, and a length of the first electrode finger 126N is longer than the length of the second electrode finger 127M.

As described above, a magnitude of the secondary distorted current I₂ₑ depends on the length of the electrode finger. Thus, a magnitude of a secondary distorted current I₂ₑ flowing out from the second electrode finger 127M is larger than a magnitude of a secondary distorted current I₂ₑ flowing into the second electrode finger 127M. As a result, a negative sign current caused by a secondary distorted current I₂ₑ flows out to an outside of the curved IDT electrode 128A. Thus, a signal of second harmonic wave distortion is likely to be output from the curved IDT electrode 128A.

For example, in a case where the acoustic wave resonator having the curved IDT electrode is used in a filter device or the like, there is a concern that filter characteristics deteriorate due to the influence of the second-harmonic wave distortion. However, in the present preferred embodiment, even in a case where the acoustic wave resonator having the curved IDT electrode is used, second-harmonic wave distortion can be reduced or prevented. The detailed description will be further continued with reference to FIG. 7.

The curved IDT electrode 128A is directly connected to the curved IDT electrode 128B by a wiring 129. In the curved IDT electrode 128B, the length of the electrode finger increases toward the left side in FIG. 7. For example, from the left side in FIG. 7, a second electrode finger 1270, a first electrode finger 126P, and a second electrode finger 1270 are sequentially arranged in this order. Then, a length of the first electrode finger 126P is shorter than a length of the second electrode finger 1270, and a length of the second electrode finger 1270 is shorter than the length of the first electrode finger 126P.

In the curved IDT electrode 128B, a magnitude of a secondary distorted current I₂ₑ flowing out from the first electrode finger 126P is smaller than a magnitude of a secondary distorted current I₂ₑ flowing into the first electrode finger 126P. As a result, a positive sign current caused by a secondary distorted current I₂ₑ flows out to an outside of the curved IDT electrode 128B.

Note that, as described above, the curved IDT electrode 128A and the curved IDT electrode 128B are directly connected by the wiring 129. A negative sign current caused by a secondary distorted current I₂ₑ flows out from the curved IDT electrode 128A to the wiring 129. A positive sign current caused by a secondary distorted current I₂ₑ flows out from the curved IDT electrode 128B to the wiring 129. Thus, the current caused by the secondary distorted current I₂ₑ can be canceled out.

Similarly to the example illustrated in FIG. 7, in the first preferred embodiment illustrated in FIG. 1, the current caused by the secondary distorted current I₂ₑ can also be canceled out. Thus, harmonic wave distortion can be reduced or prevented.

It is preferable that a difference between an electrostatic capacitance of the first acoustic wave resonator 1A and an electrostatic capacitance of the second acoustic wave resonator 1B is equal to or less than about 0.35 pF, for example. In this case, the current caused by the secondary distorted current I₂ₑ can be more reliably canceled out. Thus, harmonic wave distortion can be more reliably reduced or prevented. However, the difference between the electrostatic capacitance of the first acoustic wave resonator 1A and the electrostatic capacitance of the second acoustic wave resonator 1B is not particularly limited.

Hereinafter, further details of the first preferred embodiment will be described. Note that, the first acoustic wave resonator 1A and the second acoustic wave resonator 1B have similar configurations, except that the outer side directions are opposite to each other. Thus, the details of the configuration of the first acoustic wave resonator 1A will be described. A preferable configuration of the first acoustic wave resonator 1A to be described below is also a preferable configuration of the second acoustic wave resonator 1B.

As illustrated in FIG. 3, in the first preferred embodiment, a straight line extending in the X-propagation direction and passing through the fixed point C is defined as a reference line N. Note that, a direction of the reference line N is not limited to the above direction. The reference line N does not necessarily pass through the fixed point C. In a preferred embodiment of the present invention, a plurality of reference lines N may be defined.

As described above, the shapes of the plurality of electrode fingers of the first IDT electrode 8A in plan view are arc shapes. When an elliptical coefficient of a circle or ellipse including an arc in the shapes of the plurality of electrode fingers is defined as α2/α1, an elliptical coefficient α2/α1 is 1 in the first preferred embodiment. Note that, in a case where the shape including the arc in the shapes of the plurality of electrode fingers is an ellipse, the elliptical coefficient α2/α1 is other than 1. α1 corresponds to a dimension along a direction of an axis of a major axis and a minor axis of the ellipse passing through the intersection region F. α2 corresponds to a dimension along a direction of an axis of the major axis and the minor axis of the ellipse not passing through the intersection region F. Note that, when r is any constant, it can be represented as (x/α1)²+(y/α2)²=r² as an expression of an elliptical coefficient in an XY plane.

Each electrode finger of the first IDT electrode 8A includes a pair of end edge portions that connect a base end portion and a distal end portion to each other in plan view. Then, both end edge portions have curved shapes. In the present specification, unless otherwise specified, directions in which the electrode fingers extend are as follows. First, in a case where a virtual line parallel to the reference line N in a preferred embodiment of the present invention is drawn to connect both end edge portions in any portion of the electrode finger, a center of gravity of a portion positioned on the virtual line is defined as a representative point on the virtual line. Countless virtual lines can be drawn on the electrode finger, and there are countless representative points. Directions in which tangent lines of curves connecting the representative points extend are defined as the direction in which the electrode fingers extend. The directions in which the electrode fingers extend are different for positions on the electrode fingers. For example, in a case where the intersection region F includes a plurality of curved regions and has different reference lines N for the curved regions, it is sufficient that the reference line N of the curved region where the virtual line is drawn be set to be the direction in which the virtual line extends.

As illustrated in FIG. 3, an angle of a corner formed by a straight line passing through the fixed point C and the reference line N is defined as θ_{c}. Although there are countless straight lines passing through the fixed point C, FIG. 3 illustrates an example of the straight line. In the present specification, a positive direction of an angle θ_{c} is defined as a counterclockwise direction as viewed in plan view. More specifically, a direction from a side close to the second busbar 15A to the first busbar 14A side is the positive direction.

The intersection region F in the first IDT electrode 8A includes portions positioned on the countless straight lines passing through the fixed point C. In FIG. 3, a straight line M is illustrated as an example of the countless straight lines passing through the fixed point C and the intersection region F. For example, an acoustic wave is excited at a portion of the intersection region F positioned on the straight line M. Acoustic waves are also excited at portions positioned on the countless straight lines (not illustrated) passing through the fixed point C and the intersection region F. That is, the first acoustic wave resonator 1A includes an excitation portion positioned on the straight line M and excitation portions positioned on the countless other straight lines (not illustrated).

A direction in which the acoustic wave is excited in the intersection region F is any one of the following three directions. A first type direction is a direction perpendicular to the directions in which the electrode fingers extend. A second type direction is a direction that connects the shortest distances between adjacent electrode fingers. A third type direction is a direction parallel to an electric field vector generated between the electrode fingers.

An angle of a corner formed by an excitation direction of the acoustic wave at an intersection of a straight line passing through the fixed point C and the excitation portion in the intersection region F and the first electrode finger 16A or the second electrode finger 17A and the reference line N is defined as an excitation angle θ_{c_prop}. Note that, in the first preferred embodiment, the excitation direction of the acoustic wave is the first type direction. In the excitation portion through which the reference line N passes, the angle θ_{c} and the excitation angle θ_{c_prop} are 0°.

When the elliptical coefficient α2/α1 is 1, that is, in a case where the shape of the electrode finger is an arc, the angle θ_{c} and the excitation angle θ_{c_prop} are equal to each other. On the other hand, in a case where the shape of the electrode finger is other than an arc, the angle θ_{c} and the excitation angle θ_{c_prop} are not equal to each other. However, the angle θ_{c} and the excitation angle θ_{c_prop} substantially coincide with each other. From the above fact, it is pointed out that there is no difference between the angle θ_{c} and the excitation angle θ_{c_prop} to the extent that there is an influence that overturns operations and effects.

Since the excitation angles θ_{c_prop} are different between the excitation portions, propagation characteristics of the acoustic waves are different from each other. Thus, frequencies of the unwanted waves are different from each other between different excitation portions. Thus, the unwanted waves and transverse modes outside a pass band are dispersed. Thus, the unwanted waves and the transverse modes outside the pass band can be reduced or prevented. In the present specification, the outside of the pass band in the acoustic wave resonator means a lower-pass side of a resonant frequency and a higher-pass side of an anti-resonant frequency.

In addition, a direction in which the first envelope H1 extends intersects a direction in which the reference line N extends. Thus, the transverse modes can be effectively reduced or prevented.

Note that, in the first preferred embodiment, the resonant frequencies or the anti-resonant frequencies of all the excitation portions substantially coincide with each other. That is, the resonant frequencies or the anti-resonant frequencies substantially coincide with each other in all of the intersection regions F. Thus, resonant characteristics are unlikely to deteriorate. In the present specification, the fact that one frequency and the other frequency substantially coincide with each other means that an absolute value of a difference between both frequencies is equal to or less than about 10% with respect to a reference frequency, for example. Note that, the reference frequency means a frequency when the excitation angle θ_{c_prop} is 0°.

The angle θ_{c} of the corner formed by the straight line passing through the first envelope H1 as the end edge portion of the intersection region F close to the first busbar 14A and the fixed point C and the reference line N is defined as an intersection angle θ_{c_AP1}. The angle θ_{c} of the corner formed by the straight line passing through the second envelope H2 as the end edge portion of the intersection region F close to the second busbar 15A and the fixed point C and the reference line N is defined as an intersection angle θ_{c_AP2}. In this case, θ_{c_AP2} Sec<θ_{c_AP1}. In the first acoustic wave resonator 1A of the acoustic wave device 10 according to the comparison illustrated in FIG. 5, the intersection angle θ_{c_AP1} is about 9°, for example, The intersection angle θ_{c_AP2} is 0°, for example.

Referring back to FIG. 1, the first IDT electrode 8A includes a plurality of offset electrodes. The plurality of offset electrodes are specifically a plurality of first offset electrodes 18 and a plurality of second offset electrodes 19. One end portions of the plurality of first offset electrodes 18 are connected to the first busbar 14A. The first electrode fingers 16A and the first offset electrodes 18 are alternately arranged. One end portions of the plurality of second offset electrodes 19 are connected to the second busbar 15A. The second electrode fingers 17A and the second offset electrodes 19 are alternately arranged.

Similarly to the plurality of first electrode fingers 16A and the plurality of second electrode fingers 17A, each of the plurality of first offset electrodes 18 and the plurality of second offset electrodes 19 includes a base end portion and a distal end portion. The base end portions of the first electrode finger 16A and the first offset electrode 18 are portions connected to the first busbar 14A. The base end portions of the second electrode finger 17A and the second offset electrode 19 are portions connected to the second busbar 15A.

The distal end portion of the first electrode finger 16A and the distal end portion of the second offset electrode 19 face each other with a gap therebetween. On the other hand, the distal end portion of the second electrode finger 17A and the distal end portion of the first offset electrode 18 face each other with a gap therebetween.

Each of shapes of the plurality of first offset electrodes 18 in plan view has a curved shape. More specifically, the shapes of the plurality of first offset electrodes 18 in plan view are shapes corresponding to arcs of a plurality of concentric circles. Centers of circles including arcs in the shapes of the plurality of first offset electrodes 18 coincides with the fixed point C. On the other hand, each of shapes of the plurality of second offset electrodes 19 in plan view has a straight shape. Hereinafter, the first offset electrode 18 and the second offset electrode 19 may be simply described as an offset electrode.

The plurality of offset electrodes does not be necessarily provided. However, it is preferable that the first IDT electrode 8A includes a plurality of first offset electrodes 18 and a plurality of second offset electrodes 19. Thus, a primary mode propagated from the intersection region F toward each busbar can be reflected toward the intersection region F. As a result, a loss in the primary mode can be reduced, and characteristics of the primary mode can be improved.

It is preferable that the shapes of the plurality of first offset electrodes 18 in plan view are curved shapes. In this case, the shape of the first offset electrode 18 can be set to a shape of a condition that coincides with a frequency of the primary mode reflected by the first offset electrode 18. Thus, the reflection efficiency of reflecting the primary mode can be increased. Thus, the characteristics of the primary mode can be effectively improved.

Note that, the shapes of the plurality of first offset electrodes 18 in plan view do not have to be curved shapes. For example, the shapes of the plurality of first offset electrodes 18 may be straight shapes in plan view. In this case, a distance from the distal end portion of the first offset electrode 18 to the first busbar 14A can be shortened. Thus, an electric resistance of the first IDT electrode 8A can be reduced.

In the first preferred embodiment, a duty ratio as a metallization ratio in a region where the plurality of first electrode fingers 16A and the plurality of first offset electrodes 18 are provided is reduced toward the first busbar 14A. However, the above duty ratio may be constant. Here, the duty ratio in a region other than the intersection region is illustrated. Note that, in the present specification, the duty ratio is a duty ratio in the intersection region of the IDT electrode, unless otherwise specified.

It is preferable that the duty ratio, the electrode finger pitch, a thickness of the electrode finger, a thickness of the piezoelectric layer 6, a thickness of the intermediate layer 5 in the piezoelectric substrate 2, and the like that influences the frequency change in accordance with the angle θ_{c}. In a case where a dielectric film is provided on the piezoelectric substrate 2 to cover the first IDT electrode 8A, a thickness of the dielectric film may change in accordance with the angle θ_{c}. A plurality of parameters among the above parameters may change in accordance with the angle θ_{c}. It is preferable that at least one of the parameters changes in accordance with the angle θ_{c} such that the resonant frequencies or the anti-resonant frequencies substantially coincide with each other in all of the intersection regions F. As a result, the resonant characteristics are unlikely to deteriorate.

Similarly, in the reflector 9A and the reflector 9B, it is preferable that parameters such as a duty ratio, an electrode finger pitch of the reflector electrode finger 9c, a thickness of the reflector electrode finger 9c, a thickness of the piezoelectric layer 6, a thickness of the intermediate layer 5 in the piezoelectric substrate 2 change in accordance with the angle θ_{c}. Note that, the electrode finger pitch of the reflector electrode finger 9c is a distance between the centers of adjacent reflector electrode fingers 9c. In a case where the dielectric film is provided on the piezoelectric substrate 2 to cover the reflector 9A and the reflector 9B, the thickness of the dielectric film may change in accordance with the angle θ_{c}. A plurality of parameters among the above parameters may change in accordance with the angle θ_{c}. For example, a case where the reflector 9A and the reflector 9B are portions of the first IDT electrode 8A may be assumed. In this case, it is preferable that at least one of the above parameters changes in accordance with the angle θ_{c} such that the at least one parameter corresponds to a configuration in which the resonant frequencies or the anti-resonant frequencies substantially coincide with each other in all of the intersection regions F. As a result, the resonant characteristics are unlikely to deteriorate. The same applies to the second acoustic wave resonator 1B.

The shapes of the plurality of reflector electrode fingers 9c of the reflector 9A and the reflector 9B in plan view are shapes corresponding to arcs of a plurality of concentric circles. Centers of circles including arcs in the shapes of the plurality of reflector electrode fingers 9c coincide with the fixed point C. Note that, parameters such as the electrode finger pitch or the duty ratio of the reflector electrode finger 9c of each reflector may be different from the parameters of the electrode finger in the intersection region F of the first IDT electrode 8A. The same applies to the second acoustic wave resonator 1B. As illustrated in FIG. 2, in the first preferred

embodiment, the piezoelectric substrate 2 is the laminated substrate including the support substrate 4, the first layer 5a and the second layer 5b of the intermediate layer 5, and the piezoelectric layer 6. More specifically, the first layer 5a according to the first preferred embodiment is a high acoustic velocity film. The high acoustic velocity film is a film having a relatively high acoustic velocity. More specifically, an acoustic velocity of a bulk wave propagating through the high acoustic velocity film is higher than an acoustic velocity of the acoustic wave propagating through the piezoelectric layer 6. On the other hand, the second layer 5b is a low acoustic velocity film. The low acoustic velocity film is a film having a relatively low acoustic velocity. More specifically, an acoustic velocity of a bulk wave propagating through the low acoustic velocity film is lower than an acoustic velocity of a bulk wave propagating through the piezoelectric layer 6.

In the first preferred embodiment, in the piezoelectric substrate 2, the high acoustic velocity film, the low acoustic velocity film, and the piezoelectric layer 6 are laminated in this order. Thus, the acoustic waves can be effectively confined on the piezoelectric layer 6 side.

For example, a piezoelectric material such as aluminum nitride, lithium tantalate, lithium niobate, or crystal, ceramic such as alumina, sapphire, magnesia, silicon nitride, silicon carbide, zirconia, cordierite, mullite, steatite, forsterite, spinel, sialon, a dielectric such as aluminum oxide, silicon oxynitride, diamond-like carbon (DLC), or diamond, a semiconductor such as silicon, or a material having the above material as a primary component can also be used as the material of the high acoustic velocity film. Note that, the spinel includes an aluminum compound containing one or more elements selected from Mg, Fe, Zn, Mn, and the like, and oxygen. Examples of the spinel can include MgAl₂O₄, FeAl₂O₄, ZnAl₂O₄, and MnAl₂O₄. In the present specification, the primary component means a component whose occupying ratio exceeds 50% by weight. A material of the primary component may be in any one state of single crystal, polycrystal, and amorphous, or a mixed state thereof.

For example, a dielectric such as glass, silicon oxide, silicon oxynitride, lithium oxide, tantalum oxide, or a compound obtained by adding fluorine, carbon, or boron to silicon oxide, or a material having the above material as a primary component can be used as the material of the low acoustic velocity film.

For example, lithium tantalate, lithium niobate, zinc oxide, aluminum nitride, crystal, or lead zirconate titanate (PZT) can also be used as the material of the piezoelectric layer 6. It is preferable that lithium tantalate or lithium niobate is used as the material of the piezoelectric layer 6.

For example, a piezoelectric material such as aluminum nitride, lithium tantalate, lithium niobate, or crystal, ceramic such as alumina, sapphire, magnesia, silicon nitride, silicon carbide, zirconia, cordierite, mullite, steatite, or forsterite, a dielectric such as diamond or glass, a semiconductor such as silicon, gallium nitride, or gallium arsenic, a resin, or a material having the above material as a primary component can be used as the material of the support substrate 4. It is preferable that a high resistance silicon is used as the material of the support substrate 4. It is preferable that a volume resistivity of the material of the support substrate 4 is about 1000 Ω·cm or more, for example.

For example, one or more metals selected from the group consisting of Ti, Mo, Ru, W, Ru, Al, Pt, Ir, Cu, Cr, and Sc may be used as the material of the first IDT electrode 8A and the second IDT electrode 8B. Materials similar to the materials of the first IDT electrode 8A and the second IDT electrode 8B can be used as the material of each reflector. The first IDT electrode 8A, the second IDT electrode 8B, and each reflector may be made of a single layer metal film or may be made of a laminated metal film.

As illustrated in FIG. 1, the second busbar 15A in the first acoustic wave resonator 1A and the first busbar 14B in the second acoustic wave resonator 1B are directly connected to each other. Thus, in a case where the first acoustic wave resonator 1A and the second acoustic wave resonator 1B according to the first preferred embodiment are used, for example, for a filter device, the first acoustic wave resonator 1A and the second acoustic wave resonator 1B are connected in series to each other. However, for example, the first acoustic wave resonator 1A and the second acoustic wave resonator 1B may be connected to each other in parallel.

In a case where the first acoustic wave resonator 1A and the second acoustic wave resonator 1B are used for a ladder filter, for example, at least one of the first acoustic wave resonator 1A and the second acoustic wave resonator 1B may be used as a series arm resonator. Alternatively, for example, at least one of the first acoustic wave resonator 1A and the second acoustic wave resonator 1B may be used as a parallel arm resonator.

Note that, the first acoustic wave resonator 1A and the second acoustic wave resonator 1B may be connected in parallel to each other. An example of this parallel connection is illustrated below.

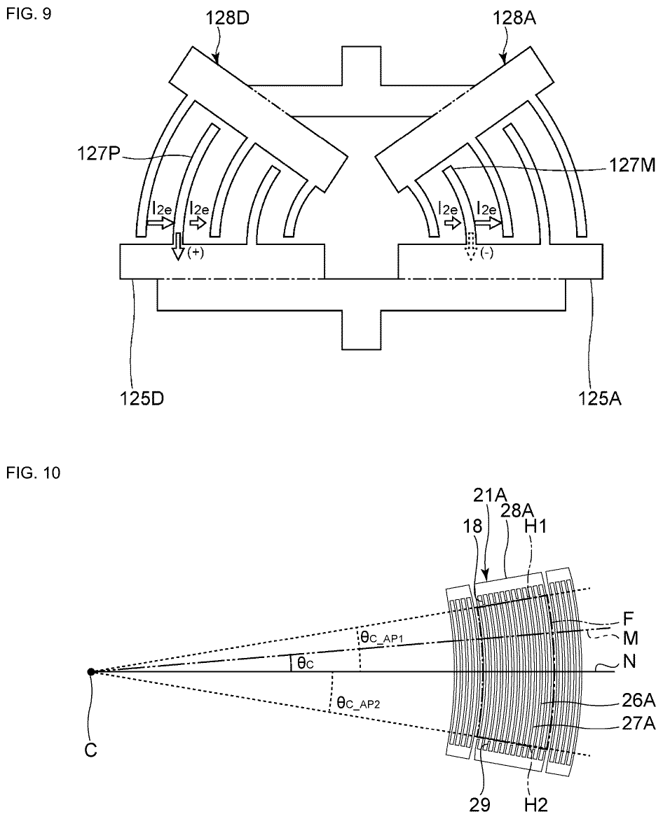

FIG. 8 is a schematic plan view of an acoustic wave device according to a modification example of the first preferred embodiment. FIG. 9 is a schematic plan view for describing a flow of secondary distorted currents in two curved IDT electrodes disposed similarly to the modification example of the first preferred embodiment. In FIG. 8, an acoustic wave resonator is illustrated by a schematic view in which two diagonal lines are added to a figure indicating an outer periphery of the acoustic wave resonator. The same applies to schematic plan views other than FIG. 8.

As illustrated in FIG. 8, in the modification example of the first preferred embodiment, a first acoustic wave resonator 1A and a second acoustic wave resonator 1D are connected in parallel to each other. The first acoustic wave resonator 1A and the second acoustic wave resonator 1D are connected without another acoustic wave resonator interposed therebetween. Specifically, a first busbar of a first IDT electrode in the first acoustic wave resonator 1A and a first busbar of a second IDT electrode in the second acoustic wave resonator 1D are connected by a wiring. A second busbar of the first IDT electrode in the first acoustic wave resonator 1A and a second busbar of the second IDT electrode in the second acoustic wave resonator 1D are connected by a wiring.

An outer side direction of the first IDT electrode in the first acoustic wave resonator 1A is a first direction D+. An outer side direction of the second IDT electrode in the second acoustic wave resonator 1D is a second direction D−. A shape of the first IDT electrode and a shape of the second IDT electrode are in a line symmetrical relationship.

A curved IDT electrode 128A illustrated in FIG. 9 is disposed similarly to the first IDT electrode. A curved IDT electrode 128D is disposed similarly to the second IDT electrode. A shape of the curved IDT electrode 128A and a shape of the curved IDT electrode 128D are in a line symmetrical relationship. In the curved IDT electrode 128A, a negative sign current caused by a secondary distorted current I₂ₑ flows out from a second electrode finger 127M toward a second busbar 125A. On the other hand, in the curved IDT electrode 128D, a positive sign current caused by a secondary distorted current I₂ₑ flows out from a second electrode finger 127P toward a second busbar 125D. Thus, the current caused by the secondary distorted current I₂ₑ can be canceled out.

Similarly to the example illustrated in FIG. 9, in the modification example of the first preferred embodiment, the current caused by the secondary distorted current I₂ₑ can be canceled out. Thus, harmonic wave distortion can be reduced or prevented.

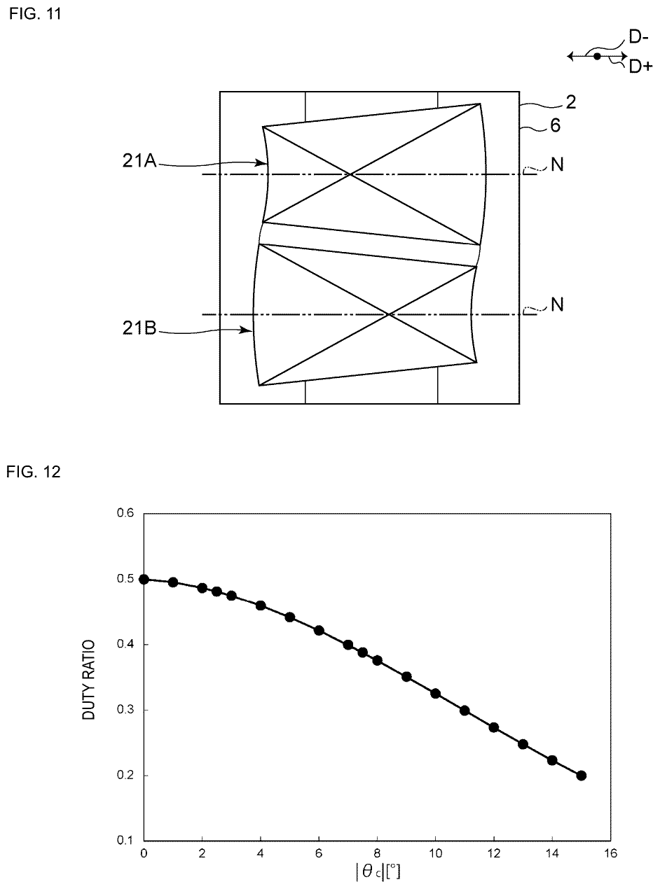

FIG. 10 is a schematic plan view for describing a configuration of a first acoustic wave resonator according to a second preferred embodiment. FIG. 11 is a schematic plan view of an acoustic wave device according to the second preferred embodiment.

As illustrated in FIG. 10, the present preferred embodiment is different from the first preferred embodiment in shapes of a first IDT electrode 28A and each reflector in a first acoustic wave resonator 21A. As illustrated in FIG. 11, the present preferred embodiment is different from the first preferred embodiment in shapes of a second IDT electrode and each reflector in a second acoustic wave resonator 21B. In other configurations than the above configuration, the acoustic wave device of the present preferred embodiment has a configuration similar to the configuration of the acoustic wave device 10 of the first preferred embodiment.

Referring back to FIG. 10, in the first IDT electrode 28A, a first envelope H1 and a second envelope H2 are disposed line symmetrically with respect to an axis of symmetry passing through a center of an intersection region F. Shapes of a plurality of first electrode fingers 26A and a plurality of second electrode fingers 27A in plan view are arc shapes. Shapes of a plurality of second offset electrodes 29 in plan view are also arc shapes. In the first IDT electrode 28A, absolute values of an intersection angle θ_{c_AP1} and an intersection angle θ_{c_AP2} are the same. Thus, the absolute value of the angle θ_{c} is 0°≤|θ_{c}|≤ |θ_{C_AP1}|=|θ_{C_AP2}|.

A shape of a second IDT electrode in the second acoustic wave resonator 21B illustrated in FIG. 11 is a shape that is line symmetrical with the shape of the first IDT electrode 28A. As in the first preferred embodiment, in the present preferred embodiment, the first acoustic wave resonator 21A and the second acoustic wave resonator 21B are connected to each other without another acoustic wave resonator interposed therebetween. Then, an outer side direction of the first IDT electrode 28A is a first direction D+, and an outer side direction of the second IDT electrode is a second direction D−. Thus, harmonic wave distortion can be reduced or prevented.

In the first IDT electrode 28A, a length of the electrode finger increases toward the first direction D+, and in the second IDT electrode, a length of the electrode finger increases toward the second direction D−. Thus, the harmonic wave distortion can be more reliably reduced or prevented.

Hereinafter, examples of design parameters of the first acoustic wave resonator 21A will be described. In the present preferred embodiment, design parameters of the second acoustic wave resonator 21B are also similar to the design parameters of the first acoustic wave resonator 21A.

Support substrate 4: material . . . Si, face azimuth . . . (111), ψ at Euler angles (φ, θ, ψ) . . . 73°

First layer 5a: material . . . SiN, thickness . . . 0.15λ

Second layer 5b: material . . . SiO₂, thickness . . . 0.15λ

Piezoelectric layer 6: material . . . rotated Y-cut 55° X-propagation of LITAO₃, thickness . . . 0.2λ

First IDT electrode 28A: material . . . Al, thickness. . . 0.05λ,

Number of pairs of electrode fingers of first IDT electrode 28A: 60 pairs

Elliptical coefficient α2/α1 in shape of electrode finger: 1

Intersection angle θ_{C_AP1}: 10°

Intersection angle θ_{C_AP2}: −10°

Wavelength λ: 2 μm

Duty ratio: 0.5 in excitation portion where angle θ_{c} is 0°

In the present preferred embodiment, duty ratios are different from each other between the plurality of excitation portions such that the resonant frequencies or the anti-resonant frequencies of all the excitation portions in the intersection region F substantially coincide with each other. That is, the duty ratio changes in accordance with the angle θ_{c}. Note that, the duty ratios are the same between the excitation portions having the same absolute value |0cl of the angle θ_{c}. Since the first IDT electrode 28A is configured as described above, the resonant characteristics of the first acoustic wave resonator 21A are unlikely to deteriorate. A relationship between the absolute value |θ_{c}| of the angle θ_{c} and the duty ratio in the present preferred embodiment is illustrated by FIG. 12.

FIG. 12 is a diagram illustrating a relationship between the absolute value |θ_{c}| of the angle θ_{c} and the duty ratio of the first IDT electrode according to the second preferred embodiment.

In the present preferred embodiment, in a case where the angle θ_{c} is 0°, the duty ratio is set to the maximum value. Then, the larger the absolute value |θ_{c}| of the angle θ_{c}, the smaller the duty ratio. As a result, the resonant frequencies or the anti-resonant frequencies substantially coincide with each other in all the intersection region F.

Hereinafter, a first modification example and a second modification example of the second preferred embodiment that are different from the second preferred embodiment only in shapes of a first IDT electrode and each reflector will be described. As in the second preferred embodiment, in the first modification example and the second modification example, the deterioration of harmonic wave distortion can be reduced or prevented.

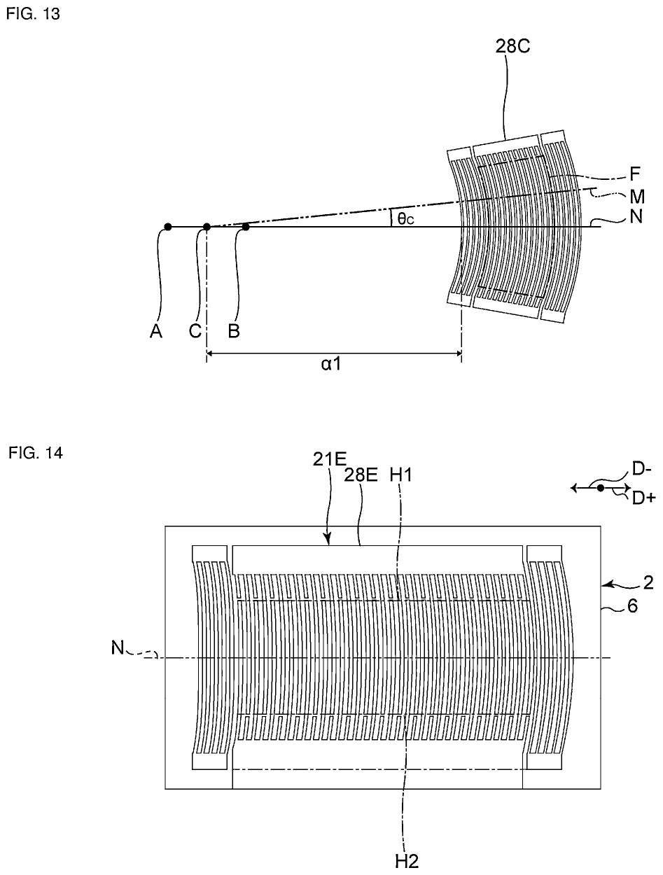

Shapes of a plurality of electrode fingers of a first IDT electrode 28C in plan view according to the first modification example illustrated in FIG. 13 are elliptical arc shapes. Specifically, the shapes of the plurality of electrode fingers of the first IDT electrode 28C in plan view are shapes corresponding to elliptical arcs of a plurality of ellipses having fixed points at the same position. Note that, a midpoint between a focus A and a focus B is a fixed point C. An elliptical coefficient α1/α2 of the shapes of the plurality of electrode fingers in plan view is other than 1.

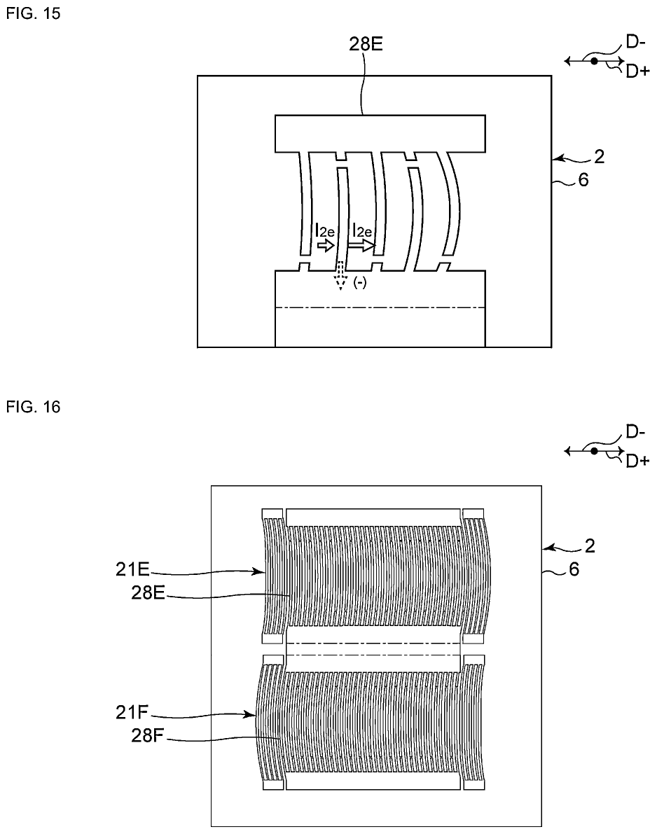

In a first IDT electrode 28E according to the second modification example illustrated in FIG. 14, a first envelope H1 and a second envelope H2 extend in parallel. A reference line N extends parallel to the first envelope H1 and the second envelope H2. Thus, in the first IDT electrode 28E, a distance between the first envelope H1 and the second envelope H2 in a direction orthogonal to a first direction D+ is constant.

However, as emphasized in FIG. 15, in the first IDT electrode 28E, a curvature in a curved shape of the electrode finger increases toward the first direction D+. Thus, a length of the electrode finger increases toward the first direction D+.

Note that, a second IDT electrode may have a configuration similar to any configuration of the first IDT electrode in the first modification example and the second modification example. In a preferred embodiment of the present invention, for example, the first IDT electrode may have any configuration of the first preferred embodiment, the second preferred embodiment, the first modification example, or the second modification example. In any one of these cases, the second IDT electrode may have a configuration similar to any configuration of the first IDT electrode in the first preferred embodiment, the second preferred embodiment, the first modification example, or the second modification example. The examples are illustrated by third to fifth modification examples of the second preferred embodiment. As in the second preferred embodiment, in the third to fifth modification examples, harmonic wave distortion can be reduced or prevented.

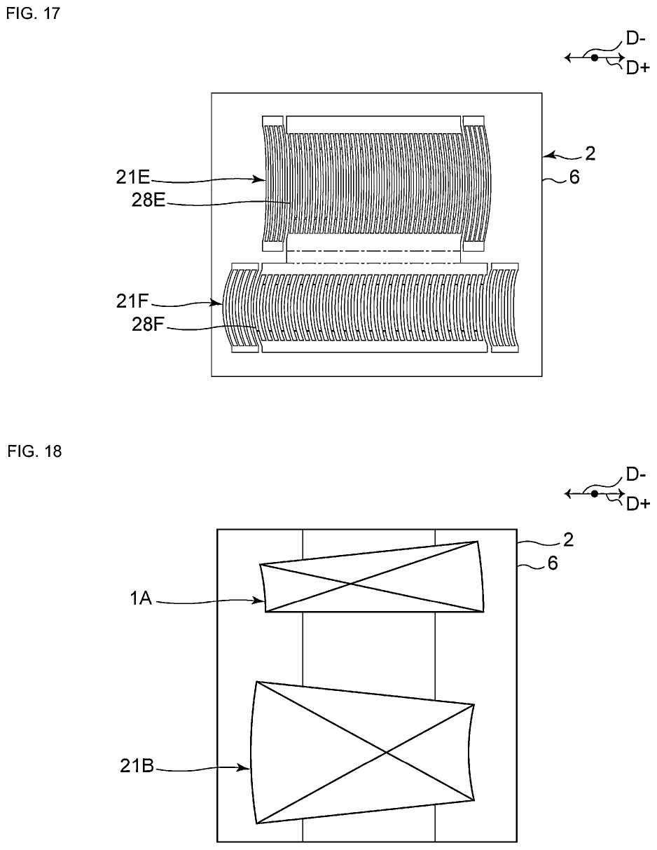

In the third modification example illustrated in FIG. 16, a first acoustic wave resonator 21E and a second acoustic wave resonator 21F are similar to the first acoustic wave resonator 21E according to the second modification example. However, shapes of a first IDT electrode 28E and each reflector in the first acoustic wave resonator 21E and shapes of a second IDT electrode 28F and each reflector in the second acoustic wave resonator 21F are in a line symmetrical relationship.

In the fourth modification example illustrated in FIG. 17, a first acoustic wave resonator 21E and a second acoustic wave resonator 21F are similar to the first acoustic wave resonator 21E according to the second modification example. However, the present modification example is different from the third modification example in that a shape of a first IDT electrode 28E and a shape of a second IDT electrode 28F are not in a line symmetrical relationship. More specifically, widths of electrode fingers and areas of intersection regions are different from each other between the first IDT electrode 28E and the second IDT electrode 28F. Note that, the number of pairs of electrode fingers and the like may be different between the first IDT electrode 28E and the second IDT electrode 28F.

Similarly to the third modification example, in the fourth modification example, outer side directions of a plurality of electrode fingers in the first IDT electrode 28E are a first direction D+. In the first IDT electrode 28E, a length of the electrode finger increases toward the first direction D+. Outer side directions of a plurality of electrode fingers in the second IDT electrode 28F are a second direction D−. In the second IDT electrode 28F, a length of the electrode finger increases toward the second direction D−.

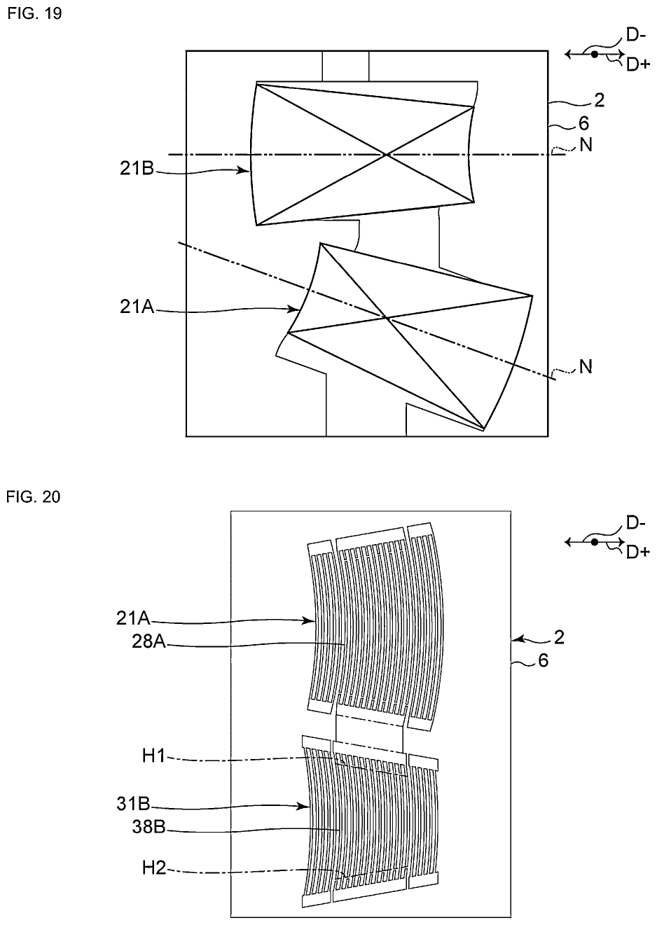

In the fifth modification example illustrated in FIG. 18, a first IDT electrode in a first acoustic wave resonator 1A is structured as in the first preferred embodiment. A second IDT electrode in a second acoustic wave resonator 21B is structured as in the second preferred embodiment. Outer side directions of a plurality of electrode fingers in the first IDT electrode of the first acoustic wave resonator 1A are a first direction D+. In the first IDT electrode, a length of the electrode finger increases toward the first direction D+. Outer side directions of a plurality of electrode fingers in the second IDT electrode of the second acoustic wave resonator 21B are a second direction D−. In the second IDT electrode, a length of the electrode finger increases toward the second direction D−.

As illustrated in FIG. 11, in the second preferred embodiment, both the reference line N in the first acoustic wave resonator 21A and the reference line N in the second acoustic wave resonator 21B extend parallel to the first direction D+ and the second direction D−. However, the present disclosure is not limited thereto.

For example, in a sixth modification example of the second preferred embodiment illustrated in FIG. 19, a direction in which the reference line N extends in the first acoustic wave resonator 21A intersects the first direction D+ and the second direction D−. On the other hand, the reference line N in the second acoustic wave resonator 21B extends parallel to the first direction D+ and the second direction D−.

However, components in a direction parallel to the first direction D+ and the second direction D− in the outer side directions of the plurality of electrode fingers in the first IDT electrode of the first acoustic wave resonator 21A are in the first direction D+. In the first IDT electrode, a length of the electrode finger increases toward the first direction D+. The outer side directions of the plurality of electrode fingers in the second IDT electrode of the second acoustic wave resonator 21B are the second direction D− out of the first direction D+ and the second direction D−. In the second IDT electrode, a length of the electrode finger increases toward the second direction D−. Thus, as in the second preferred embodiment, harmonic wave distortion can be reduced or prevented. That is, in the first acoustic wave resonator 21A and the second acoustic wave resonator 21B, the outer side directions are not limited to being opposite to each other by 180°, and the present invention includes directions as long as the components in the direction parallel to the first direction D+ and the second direction D− in the outer side direction are in opposite directions to each other.

FIG. 20 is a schematic plan view of an acoustic wave device according to a third preferred embodiment.

The present preferred embodiment is different from the second preferred embodiment in shapes and dispositions of a second IDT electrode 38B and each reflector in a second acoustic wave resonator 31B. In other configurations than the above configuration, the acoustic wave device of the present preferred embodiment has a configuration similar to the configuration of the acoustic wave device of the second preferred embodiment.

In the second IDT electrode 38B, outer side directions of ae plurality of electrode fingers are a first direction D+. In the second IDT electrode 38B, a distance between a first envelope H1 and a second envelope H2 in a direction orthogonal to the first direction D+ becomes shorter toward the first direction D+. Then, in the second IDT electrode 38B, a length of the electrode finger becomes shorter toward a first direction D+. That is, in the second IDT electrode 38B, a length of the electrode finger increases toward the second direction D−.

On the other hand, as in the second preferred embodiment, in a first IDT electrode 28A, outer side directions of a plurality of electrode fingers are the first direction D+. In the first IDT electrode 28A, a length of the electrode finger increases toward the first direction D+. In this case, a current caused by a secondary distorted current I₂ₑ flowing out from the first IDT electrode 28A and the second IDT electrode 38B can also be canceled out. Thus, harmonic wave distortion can be reduced or prevented.

As described above, the outer side directions of the plurality of electrode fingers of the first IDT electrode 28A and the second IDT electrode 38B may be the same direction. In this case, in the first IDT electrode 28A and the second IDT electrode 38B, it is sufficient that directions in which the electrode fingers are lengthened be opposite to each other.

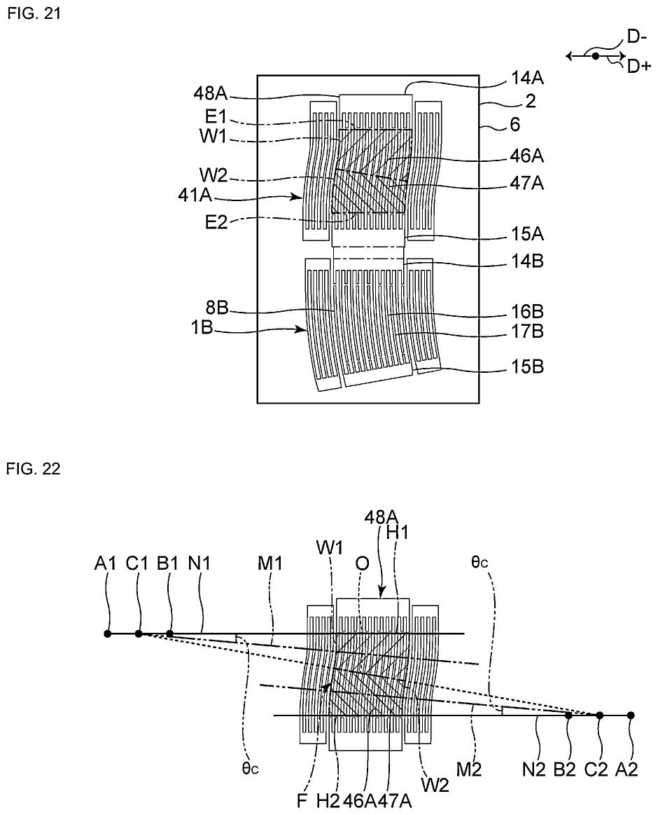

FIG. 21 is a schematic plan view of an acoustic wave device according to a fourth preferred embodiment. FIG. 22 is a schematic plan view for describing a configuration of a first IDT electrode according to the fourth preferred embodiment.

As illustrated in FIG. 21, the present preferred embodiment is different from the first preferred embodiment in shapes and dispositions of a first IDT electrode 48A and each reflector in a first acoustic wave resonator 41A. In other configurations than the above configuration, the acoustic wave device of the present preferred embodiment has a configuration similar to the configuration of the acoustic wave device 10 of the first preferred embodiment.

As illustrated in FIG. 22, an intersection region F of the first IDT electrode 48A includes a plurality of curved regions. Specifically, the plurality of curved regions are a first curved region W1 and a second curved region W2. The first curved region W1 includes a first envelope H1. The second curved region W2 includes a second envelope H2. A boundary line O between the first curved region W1 and the second curved region W2 is a straight line.

More specifically, shapes of a plurality of first electrode fingers 46A and a plurality of second electrode fingers 47A of the first IDT electrode 48A have inflection points in plan view. In the present specification, the inflection point is a point where curves different from each other are connected or a point where a curve and a straight line are connected to each other. In a case where the curves different from each other are connected to each other at the inflection point, outer side directions of the electrode fingers are different with the inflection point as a boundary.

In the present preferred embodiment, a portion where a left direction is the outer side direction and a portion where a right direction is the outer side direction in FIG. 22 are connected to each other at the inflection point. As described above, in the present preferred embodiment, the two curved shapes are inverted from each other with the inflection point as a boundary. The same applies to each reflector. A straight line that connects the inflection points of the plurality of electrode fingers in the first IDT electrode 48A is a boundary line O between the first curved region W1 and the second curved region W2.

In each curved region, the shapes of the plurality of electrode fingers in plan view are single arc shape or elliptical arc shapes. However, in the first IDT electrode 48A of the present preferred embodiment, the shape of each of the plurality of electrode fingers in plan view is a single elliptical arc in each curved region. Thus, each of the shapes of the plurality of electrode fingers in the first IDT electrode 48A in plan view is a shape obtained by connecting two elliptical arcs to each other.

In the first curved region W1, the elliptical arc of each of the shapes of the plurality of electrode fingers as viewed in plan view is a shape corresponding to an elliptical arc of each of a plurality of ellipses having a fixed point at the same position. A common fixed point of these ellipses can be defined as a first fixed point C1. Note that, the fixed point C1 is a midpoint between a focus A1 and a focus B1.

In the second curved region W2, the elliptical arc of each of the shapes of the plurality of electrode fingers as viewed in plan view is also a shape corresponding to an elliptical arc of each of the plurality of ellipses having a fixed point at the same position. A common fixed point of these ellipses can be defined as a second fixed point C2. Note that, the fixed point C2 is a midpoint between a focus A2 and a focus B2. That is, in the present preferred embodiment, two fixed points are defined. The fixed point C1 and the fixed point C2 face each other with the first IDT electrode 48A interposed therebetween.

As described above, each of the shapes of the plurality of electrode fingers in the first IDT electrode 48A may include at least two curved portions having different outer side directions in the intersection region F. Then, each of the shapes of the plurality of electrode fingers in plan view may include at least one inflection point in the intersection region F.

In the first IDT electrode 48A, two lines of a reference line N1 and a reference line N2 are defined. Specifically, the reference line N1 is a straight line obtained by extending the first envelope H1 and is a straight line passing through the fixed point C1. The reference line N2 is a straight line obtained by extending the second envelope H2 and is a straight line passing through the fixed point C2.

An angle of a corner formed by a straight line passing through the fixed point C1 in the first curved region W1 and the first curved region W1 and the reference line N1 is an angle θ_{c} in the first curved region W1. A straight line M1 in FIG. 22 is an example of the straight line passing through the fixed point C1 and the first curved region W1. On the other hand, an angle of a corner formed by a straight line passing through the fixed point C2 in the second curved region W2 and the second curved region W2 and the reference line N2 is an angle θ_{c} in the second curved region W2. A straight line M2 in FIG. 22 is an example of the straight line passing through the fixed point C2 and the second curved region W2.

Referring back to FIG. 21, an area of the first curved region W1 is larger than an area of the second curved region W2. In this case, in the first IDT electrode 48A, the first curved region W1 is dominant in a direction of a current caused by the secondary distorted current I₂ₑ. Then, in the first curved region W1, the outer side direction is the first direction D+. In the first curved region W1, a length of the electrode finger increases toward the first direction D+. Thus, when one second electrode finger 47A is used as a reference, a magnitude of a secondary distorted current I₂ₑ flowing out from the second electrode finger 47A is larger than a magnitude of a secondary distorted current I₂ₑ flowing into the second electrode finger 47A. Thus, a negative sign current caused by a secondary distorted current I₂ₑ flows out from the second electrode finger 47A to a second busbar 15A side.

On the other hand, a second IDT electrode 8B is structured as in the first preferred embodiment. Specifically, in the second IDT electrode 8B, outer side directions are the second direction D−. In the second IDT electrode 8B, the length of the electrode finger increases toward the second direction D−. Thus, a positive sign current caused by a secondary distorted current I₂ₑ flows out from a first electrode finger 16B to a first busbar 14B side.

Note that, in the present preferred embodiment, the second busbar 15A of the first IDT electrode 48A and the first busbar 14B of the second IDT electrode 8B are directly connected to each other. As a result, a current caused by a secondary distorted current I₂ₑ flowing out from the first IDT electrode 48A and the second IDT electrode 8B can be canceled out. Thus, harmonic wave distortion can be reduced or prevented.

In the present preferred embodiment, an intersection region of the second IDT electrode 8B includes only one curved region. Thus, in the second IDT electrode 8B, an area of a region whose outer side directions are the first direction D+ is 0. Thus, a total area of regions whose outer side directions are the second direction D− is larger than a total area of regions whose outer side directions are the first direction D+.

However, the intersection region of the second IDT electrode 8B may include a plurality of curved regions. In this case, it is sufficient that a total area of regions whose outer side directions are the second direction D− also be larger than a total area of regions whose outer side directions are the first direction D+. Thus, a current caused by a secondary distorted current I₂ₑ flowing out from the first IDT electrode 48A and the second IDT electrode 8B can be canceled out.

Alternatively, in the first IDT electrode 48A and the second IDT electrode 8B, it is sufficient that directions in which the electrode fingers are lengthened be opposite to each other. For example, in the first IDT electrode 48A, an area of the first curved region W1 is larger than an area of the second curved region W2, and a length of the electrode finger becomes larger toward any one of the first direction D+ and the second direction D−. In this case, in the second IDT electrode 8B, it is sufficient that a length of the electrode finger become longer toward the other of the first direction D+ and the second direction D−. Thus, a current caused by a secondary distorted current I₂ₑ flowing out from the first IDT electrode 48A and the second IDT electrode 8B can be canceled out.

Hereinafter, a modification example of the fourth preferred embodiment that is different from the fourth preferred embodiment only in shapes of a first IDT electrode, a second IDT electrode, and each reflector will be described.

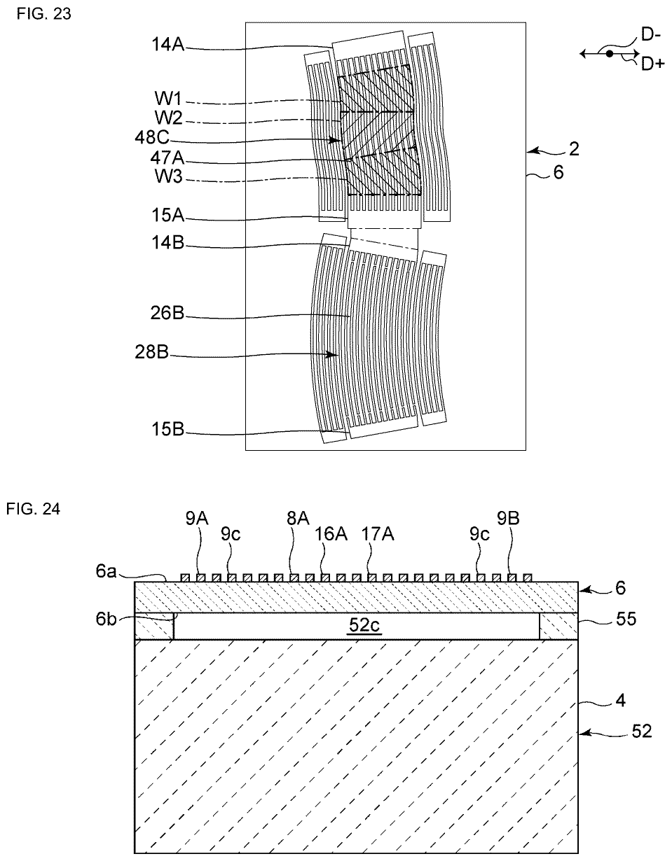

In the modification example of the fourth preferred embodiment illustrated in FIG. 23, an intersection region of a first IDT electrode 48C includes a first curved region W1, a second curved region W2, and a third curved region W3. The first curved region W1, the second curved region W2, and the third curved region W3 are arranged in a direction in which a first busbar 14A and a second busbar 15A face each other. More specifically, the first curved region W1 and the third curved region W3 face each other with the second curved region W2 interposed therebetween.

In the first curved region W1 and the third curved region W3, outer side directions of a plurality of electrode fingers are a first direction D+. In the second curved region W2, outer side directions of a plurality of electrode fingers are a second direction D−. The total area of the first curved region W1 and the third curved region W3 is larger than an area of the second curved region W2. In the first IDT electrode 48C, a length of the electrode finger increases toward the first direction D+.

Here, when a region where the outer side directions of the plurality of electrode fingers are the first direction D+ is defined as a first region, and a region where the outer side directions of the plurality of electrode fingers are the second direction D− is defined as a second region, the first curved region W1 and the third curved region W3 are the first regions. The second curved region W2 is the second region. In the first IDT electrode 48C, a total area of the first regions is larger than a total area of the second region. In this case, in the first IDT electrode 48C, the first region is dominant in a direction of a current caused by a secondary distorted current I₂ₑ. Thus, as in the fourth preferred embodiment, a negative sign current caused by a secondary distorted current I₂ₑ flows out from a second electrode finger 47A to the second busbar 15A side.

On the other hand, a second IDT electrode 28B is structured as in the second preferred embodiment. Specifically, in the second IDT electrode 28B, outer side directions are the second direction D−. In the second IDT electrode 28B, a length of the electrode finger is longer toward the second direction D−. Thus, a positive sign current caused by a secondary distorted current I₂ₑ flows out from a first electrode finger 26B to the first busbar 14B side. Thus, a current caused by a secondary distorted current I₂ₑ flowing out from the first IDT electrode 48C and the second IDT electrode 28B can be canceled out. Thus, harmonic wave distortion can be reduced or prevented.

Incidentally, a laminated structure of the piezoelectric substrate is not limited to the configuration illustrated in FIG. 2. According to a fifth preferred embodiment, an example in which an acoustic wave device includes a piezoelectric substrate different from the piezoelectric substrate of the first preferred embodiment will be described.

FIG. 24 is a schematic elevational cross-sectional view of an acoustic wave device according to the fifth preferred embodiment.

The present preferred embodiment is different from the first preferred embodiment in a laminated structure of a piezoelectric substrate 52. In FIG. 24, a first IDT electrode 8A is illustrated. However, although not illustrated, a second IDT electrode 8B similar to the second IDT electrode of the first preferred embodiment is also provided on the piezoelectric substrate 52. In other configurations than the above configuration, the acoustic wave device of the present preferred embodiment has a configuration similar to the configuration of the acoustic wave device 10 of the first preferred embodiment.

The piezoelectric substrate 52 includes a support substrate 4, an intermediate layer 55, and a piezoelectric layer 6. The intermediate layer 55 is provided on the support substrate 4. The piezoelectric layer 6 is provided on the intermediate layer 55. In the present preferred embodiment, the intermediate layer 55 has a frame shape. That is, the intermediate layer 55 includes through-holes. The support substrate 4 closes one of the through-holes of the intermediate layer 55. The piezoelectric layer 6 closes the other of the through-holes of the intermediate layer 55. As a result, a hollow portion 52c is provided in the piezoelectric substrate 52. A portion of the piezoelectric layer 6 and a portion of the support substrate 4 face each other with the hollow portion 52c interposed therebetween.

In the present preferred embodiment, primary modes can be reflected to the piezoelectric layer 6 side. Thus, energy of an acoustic wave can be effectively confined on the piezoelectric layer 6 side. In addition, as in the first preferred embodiment, harmonic wave distortion can be reduced or prevented.

Hereinafter, a first modification example and a second modification example of the fifth preferred embodiment that are different from the fifth preferred embodiment only in a laminated structure of a piezoelectric substrate will be described. As in the fifth preferred embodiment, in the first modification example and the second modification example, the harmonic wave distortion can be reduced or prevented, and the energy of the acoustic wave can be effectively confined on a piezoelectric layer 6 side.

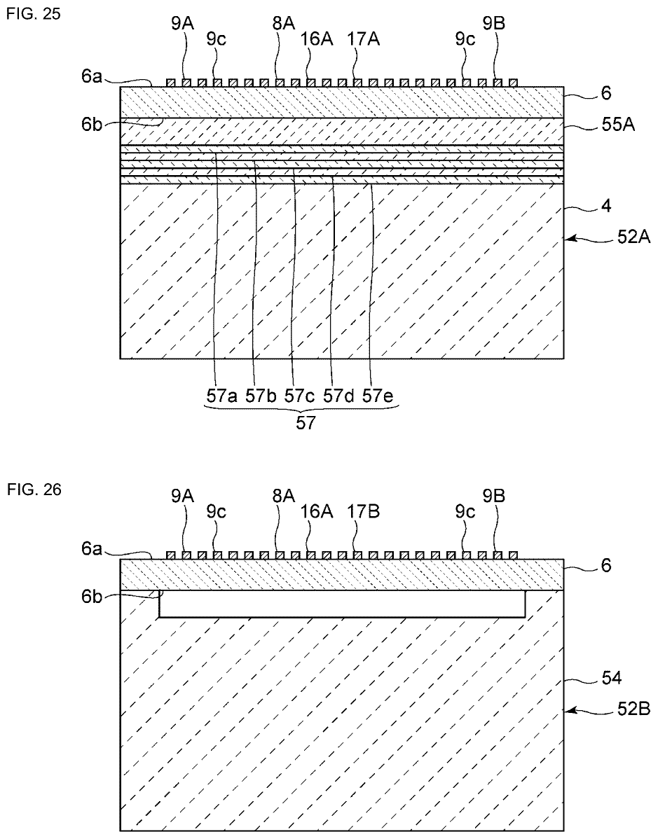

In the first modification example illustrated in FIG. 25, a piezoelectric substrate 52A includes a support substrate 4, an acoustic reflective film 57, an intermediate layer 55A, and the piezoelectric layer 6. The acoustic reflective film 57 is provided on the support substrate 4. The intermediate layer 55A is provided on the acoustic reflective film 57. The piezoelectric layer 6 is provided on the intermediate layer 55A. The intermediate layer 55A is a low acoustic velocity film.

The acoustic reflective film 57 is a multilayer body of a plurality of acoustic impedance layers. Specifically, the acoustic reflective film 57 includes a plurality of low acoustic impedance layers and a plurality of high acoustic impedance layers. The high acoustic impedance layer is a layer having a relatively high acoustic impedance. More specifically, the plurality of high acoustic impedance layers of the acoustic reflective film 57 are a high acoustic impedance layer 57a, a high acoustic impedance layer 57c, and a high acoustic impedance layer 57e. On the other hand, the low acoustic impedance layer is a layer having a relatively low acoustic impedance. More specifically, the plurality of low acoustic impedance layers of the acoustic reflective film 57 are a low acoustic impedance layer 57b and a low acoustic impedance layer 57d. The low acoustic impedance layers and the high acoustic impedance layers are alternately laminated. Note that, the high acoustic impedance layer 57a is a layer positioned closest to the piezoelectric layer 6 side in the acoustic reflective film 57.

The acoustic reflective film 57 includes two low acoustic impedance layers and three high acoustic impedance layers. However, it is sufficient that the acoustic reflective film 57 includes at least one low acoustic impedance layer and at least one high acoustic impedance layer.

For example, silicon oxide or aluminum can be used as a material of the low acoustic impedance layer. For example, metal such as platinum or tungsten, or a dielectric such as aluminum nitride or silicon nitride can be used as the material of the high acoustic impedance layer. Note that, a material of the intermediate layer 55A may be the same as the material of the low acoustic impedance layer.

In the second modification example illustrated in FIG. 26, a piezoelectric substrate 52B includes a support substrate 54 and a piezoelectric layer 6. The piezoelectric layer 6 is provided directly on the support substrate 54. More specifically, the support substrate 54 includes a recessed portion. The piezoelectric layer 6 is provided on the support substrate 54 to close the recessed portion. As a result, a hollow portion is provided in the piezoelectric substrate 52B. The hollow portion overlaps at least a portion of the first IDT electrode 8A in plan view.

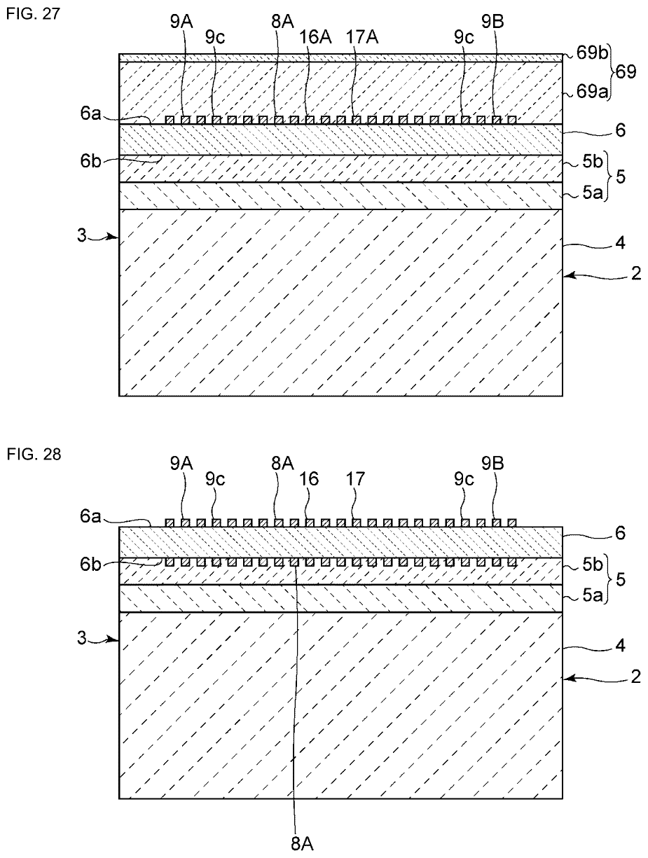

FIG. 27 is a schematic elevational cross-sectional view of an acoustic wave device according to a sixth preferred embodiment.

The present preferred embodiment is different from the first preferred embodiment in that a first IDT electrode 8A is embedded in a protective film 69. Although not illustrated, the present preferred embodiment is also different from the first preferred embodiment in that a second IDT electrode 8B illustrated in FIG. 1 is embedded in the protective film 69. In other configurations than the above configuration, the acoustic wave device of the present preferred embodiment has a configuration similar to the configuration of the acoustic wave device 10 of the first preferred embodiment.

Specifically, the protective film 69 is provided on the piezoelectric layer 6 to cover the first IDT electrode 8A. A thickness of the protective film 69 is larger than a thickness of the first IDT electrode 8A. The first IDT electrode 8A is embedded in the protective film 69. As a result, the first IDT electrode 8A is unlikely to be damaged. Similarly, the second IDT electrode 8B is also unlikely to be damaged.

The protective film 69 includes a first protective layer 69a and a second protective layer 69b. The first IDT electrode 8A and the second IDT electrode 8B are embedded in the first protective layer 69a. The second protective layer 69b is provided on the first protective layer 69a. Thus, a plurality of effects can be obtained by the protective film 69. Specifically, in the present preferred embodiment, silicon oxide is used as a material of the first protective layer 69a. As a result, an absolute value of a temperature coefficient of frequency (TCF) in the acoustic wave device can be reduced. Thus, temperature characteristics of the acoustic wave device can be improved. Silicon nitride is used for the second protective layer 69b. As a result, humidity resistance of the acoustic wave device can be improved.

In addition, in the present preferred embodiment, the first IDT electrode 8A and the second IDT electrode 8B are structured and disposed as in the first preferred embodiment. Thus, harmonic wave distortion can be reduced or prevented.

Note that, the materials of the first protective layer 69a and the second protective layer 69b are not limited to the above materials. The protective film 69 may be a single layer or a multilayer body of three or more layers.

FIG. 28 is a schematic elevational cross-sectional view of an acoustic wave device according to a seventh preferred embodiment.

The present preferred embodiment is different from the first preferred embodiment in that a first IDT electrode 8A is provided on both a first primary surface 6a and a second primary surface 6b of a piezoelectric layer 6. Although not illustrated, the present preferred embodiment is also different from the first preferred embodiment in that a second IDT electrode 8B illustrated in FIG. 1 is provided on both the first primary surface 6a and the second primary surface 6b of the piezoelectric layer 6. Note that, the first IDT electrode 8A and the second IDT electrode 8B provided on the second primary surface 6b are embedded in a second layer 5b in an intermediate layer 5. In other configurations than the above configuration, the acoustic wave device of the present preferred embodiment has a configuration similar to the configuration of the acoustic wave device 10 of the first preferred embodiment.

The first IDT electrode 8A provided on the first primary surface 6a and the first IDT electrode 8A provided on the second primary surface 6b of the piezoelectric layer 6 face each other with the piezoelectric layer 6 interposed therebetween. There is The second IDT electrode 8B provided on the first primary surface 6a and the second IDT electrode 8B provided on the second primary surface 6b of the piezoelectric layer 6 face each other with the piezoelectric layer 6 interposed therebetween.

In the acoustic wave device of the present preferred embodiment, the first IDT electrode 8A and the second IDT electrode 8B are provided on the first primary surface 6a as in the first preferred embodiment. Then, the first IDT electrode 8A and the second IDT electrode 8B are connected to each other without the functional electrode of the other acoustic wave resonator interposed therebetween. The same applies to the second primary surface 6b. Thus, as in the first preferred embodiment, harmonic wave distortion can be reduced or prevented.

Note that, for example, design parameters of the first IDT electrodes 8A provided on the first primary surface 6a and the second primary surface 6b of the piezoelectric layer 6 may be different from each other. For example, design parameters of the second IDT electrodes 8B provided on the first primary surface 6a and the second primary surface 6b may be different from each other.

Hereinafter, first to third modification examples of the seventh preferred embodiment that are different from the seventh preferred embodiment in at least one of a configuration of an electrode provided on a second primary surface of a piezoelectric layer or a laminated structure of a piezoelectric substrate will be described. As in the seventh preferred embodiment, in the first to third modification examples, harmonic wave distortion can be reduced or prevented.

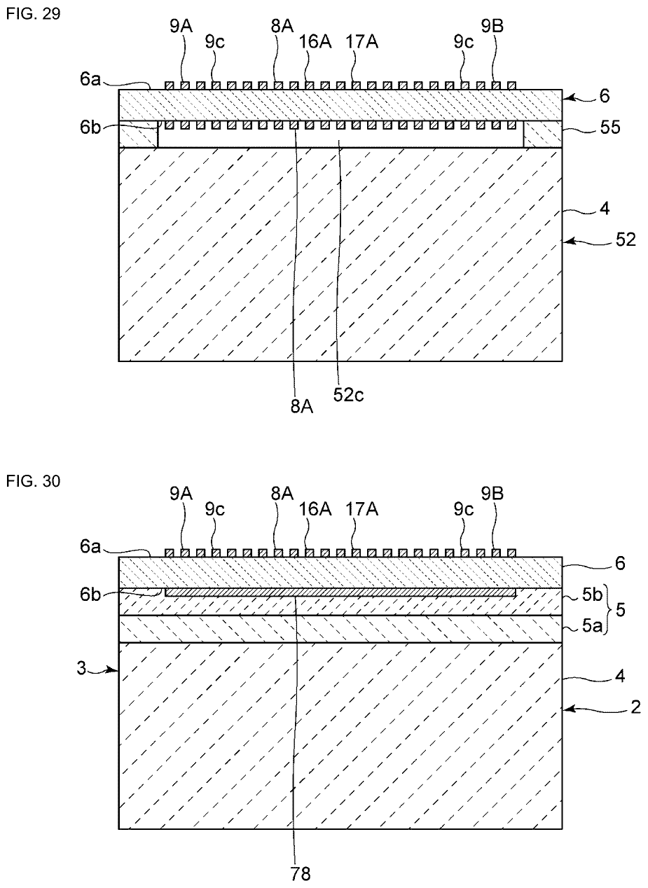

In the first modification example illustrated in FIG. 29, a piezoelectric substrate 52 is provided as in the fifth preferred embodiment. Specifically, a piezoelectric substrate 52 includes a support substrate 4, an intermediate layer 55, and a piezoelectric layer 6. A first IDT electrode 8A provided on a second primary surface 6b of the piezoelectric layer 6 is positioned in a hollow portion 52c. Although not illustrated, a second IDT electrode 8B provided on the second primary surface 6b is also positioned in the hollow portion 52c.

In the second modification example illustrated in FIG. 30, a plate-shaped electrode 78 is provided on the second primary surface 6b of the piezoelectric layer 6. The first IDT electrode 8A and the electrode 78 face each other with the piezoelectric layer 6 interposed therebetween. Note that, another electrode 78 is also provided on the second primary surface 6b to face the second IDT electrode 8B. Each electrode 78 is embedded in a second layer 5b.

In the third modification example illustrated in FIG. 31, a piezoelectric substrate 52 is structured as in the first modification example, and an electrode 78 similar to the electrode of the second modification example is provided the second primary surface 6b of the piezoelectric layer 6. The electrode 78 is positioned in the hollow portion 52c.

In the fifth to seventh preferred embodiments and each of the modification examples, examples in which the first IDT electrode and the second IDT electrode are structured and disposed as in the first preferred embodiment are illustrated. However, in the piezoelectric substrates of the fifth to seventh preferred embodiments and each of the modification examples, even in a case where the configurations and dispositions of the plurality of IDT electrodes have a configuration and disposition of the present invention other than the configurations and dispositions of the first preferred embodiment, can be used.

An acoustic wave device according to a preferred embodiment of the present invention may be a filter device. An example of this configuration is illustrated below.

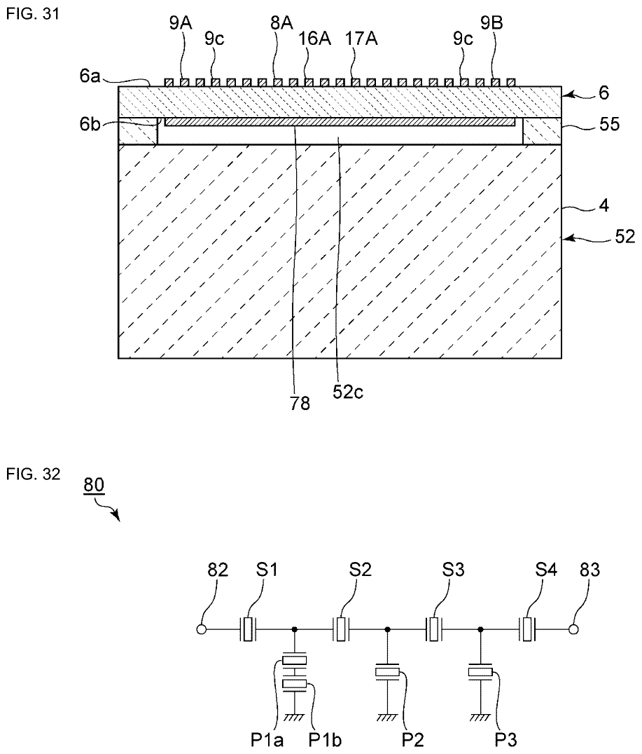

FIG. 32 is a circuit diagram of an acoustic wave device according to an eighth preferred embodiment.

An acoustic wave device 80 of the present preferred embodiment is a ladder filter. The acoustic wave device 80 includes a first signal terminal 82, a second signal terminal 83, a plurality of series arm resonators, and a plurality of parallel arm resonators. In the acoustic wave device 80, all the series arm resonators and all the parallel arm resonators are acoustic wave resonators. A plurality of acoustic wave resonators include a plurality of IDT electrodes on the piezoelectric substrate.

The first signal terminal 82 is an antenna terminal. The antenna terminal is connected to an antenna. However, the first signal terminal 82 does not necessarily need to be an antenna terminal. The first signal terminal 82 and the second signal terminal 83 may be, for example, electrode pads or wirings.

Specifically, the plurality of series arm resonators of the present preferred embodiment are a series arm resonator S1, a series arm resonator $2, a series arm resonator $3, and a series arm resonator S4. The plurality of series arm resonators are connected in series to each other between the first signal terminal 82 and the second signal terminal 83. Specifically, the plurality of parallel arm resonators are a parallel arm resonator P1a, a parallel arm resonator P1b, a parallel arm resonator P2, and a parallel arm resonator P3.

The parallel arm resonator P1a and the parallel arm resonator P1b are connected in series to each other between a connection point between the series arm resonator S1 and the series arm resonator S2 and a ground potential. The parallel arm resonator P2 is connected between a connection point between the series arm resonator S2 and the series arm resonator S3 and a ground potential. The parallel arm resonator P3 is connected between a connection point between the series arm resonator S3 and the series arm resonator S4 and a ground potential. Note that, a circuit configuration of the acoustic wave device 80 is not limited to the above configuration. The acoustic wave device 80 may include, for example, a longitudinally coupled resonator acoustic wave filter.

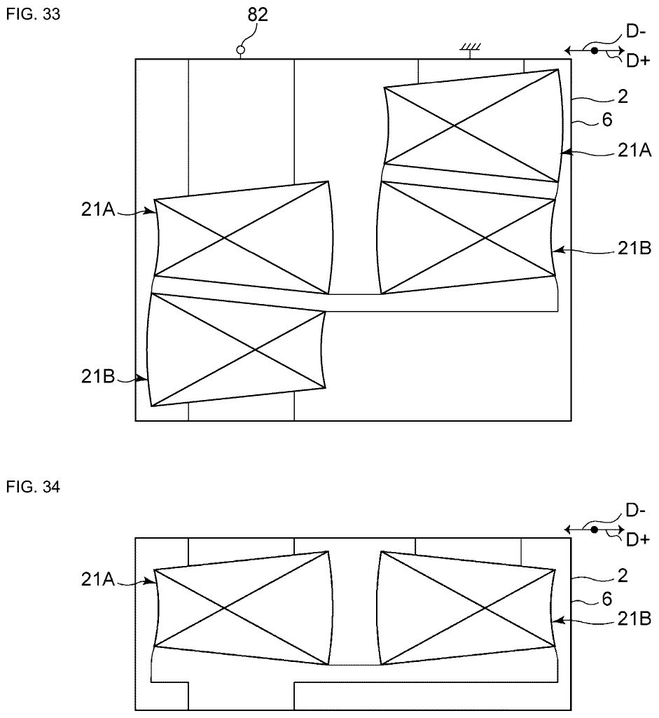

FIG. 33 is a schematic plan view illustrating the plurality of parallel arm resonators and the plurality of series arm resonators according to the eighth preferred embodiment.

In the present preferred embodiment, two sets of a first acoustic wave resonator 21A and a second acoustic wave resonator 21B are provided. Specifically, the series arm resonator S1 illustrated in FIG. 32 is the first acoustic wave resonator 21A illustrated in FIG. 33. The series arm resonator S2 is the second acoustic wave resonator 21B. The first acoustic wave resonator 21A and the second acoustic wave resonator 21B are structured as in the second preferred embodiment. Thus, a current caused by a secondary distorted currents I₂ₑ flowing out from the first IDT electrode of the series arm resonator S1 and the second IDT electrode of the series arm resonator S2 can be canceled out. Thus, harmonic wave distortion can be reduced or prevented.

On the other hand, the parallel arm resonator P1b illustrated in FIG. 32 is the first acoustic wave resonator 21A illustrated in FIG. 33. The parallel arm resonator P1a is the second acoustic wave resonator 21B. The first acoustic wave resonator 21A and the second acoustic wave resonator 21B are structured as in the second preferred embodiment. Thus, harmonic wave distortion can be reduced or prevented.

Note that, although not illustrated, the IDT electrode in the series arm resonator S3 is a straight IDT electrode.

It is sufficient that the acoustic wave device that is the filter device include at least one set of a first acoustic wave resonator and a second acoustic wave resonator. The first acoustic wave resonator and the second acoustic wave resonator may include configurations of a first acoustic wave resonator and a second acoustic wave resonator according to preferred embodiments of the present invention other than the second preferred embodiment.

The dispositions of the first acoustic wave resonator and the second acoustic wave resonator on the circuit are not limited to the above dispositions. Hereinafter, a first modification example and a second modification example of the eighth preferred embodiment that are different from the eighth preferred embodiment only in the dispositions of the first acoustic wave resonator and the second acoustic wave resonator will be described. As in the eighth preferred embodiment, in the first modification example and the second modification example, harmonic wave distortion can be reduced or prevented.

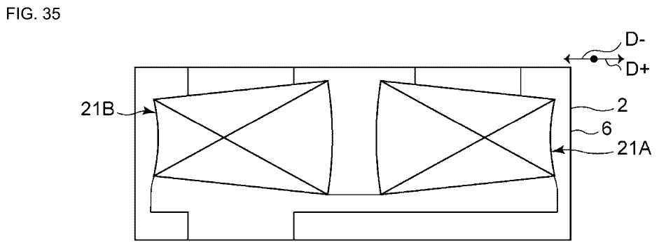

In the first modification example illustrated in FIG. 34, a series arm resonator S2 is a first acoustic wave resonator 21A, and a parallel arm resonator P2 is a second acoustic wave resonator 21B. In the second modification example illustrated in FIG. 35, a parallel arm resonator P2 is a first acoustic wave resonator 21A, and a series arm resonator S2 is a second acoustic wave resonator 21B.

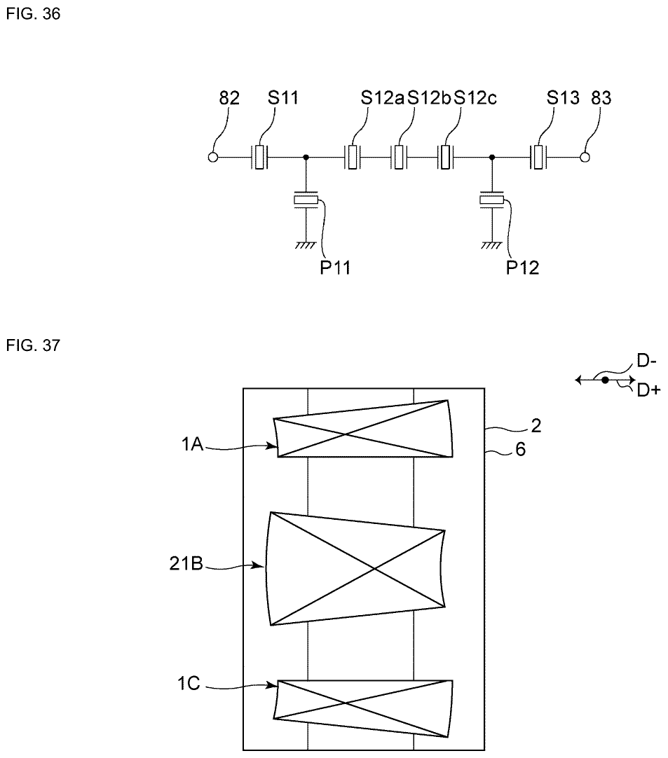

FIG. 36 is a circuit diagram of an acoustic wave device according to a ninth preferred embodiment. FIG. 37 is a schematic plan view illustrating a plurality of series arm resonators according to the ninth preferred embodiment.

As illustrated in FIGS. 36 and 37, the present preferred embodiment is different from the eighth preferred embodiment in a circuit configuration. Note that, the acoustic wave device of the present preferred embodiment is a ladder filter. The present preferred embodiment is different from the eighth preferred embodiment in that a third acoustic wave resonator 1C is included. The present preferred embodiment is different from the eighth preferred embodiment in a configuration of a first acoustic wave resonator 1A. Further, the present preferred embodiment is different from the eighth preferred embodiment in dispositions of the first acoustic wave resonator 1A and a second acoustic wave resonator 21B. In other configurations than the above configuration, the acoustic wave device of the present preferred embodiment has a configuration similar to the configuration of the acoustic wave device of the eighth preferred embodiment.

As illustrated in FIG. 36, a plurality of series arm resonators of the present preferred embodiment specifically include a series arm resonator S11, a series arm resonator S12a, a series arm resonator S12b, a series arm resonator S12c, and a series arm resonator S13. The plurality of series arm resonators are connected in series to each other between the first signal terminal 82 and the second signal terminal 83. Specifically, a plurality of parallel arm resonators are a parallel arm resonator P11 and a parallel arm resonator P12.

The parallel arm resonator P11 is connected between a connection point between the series arm resonator S11 and the series arm resonator S12a and a ground potential. The parallel arm resonator P12 is connected between a connection point between the series arm resonator S12c and the series arm resonator S13 and a ground potential.

The series arm resonator S12a illustrated in FIG. 36 is the first acoustic wave resonator 1A illustrated in FIG. 37. The series arm resonator S12b is the second acoustic wave resonator 21B. The first acoustic wave resonator 1A is structured as in the first preferred embodiment. On the other hand, the second acoustic wave resonator 21B is structured as in the second preferred embodiment.

The series arm resonator S12c is a third acoustic wave resonator 1C. The third acoustic wave resonator 1C has a configuration similar to the configuration of the first acoustic wave resonator 1A according to the first preferred embodiment. Specifically, the third acoustic wave resonator 1C includes a third IDT electrode and a pair of reflectors. The third IDT electrode is a curved IDT electrode. Outer side directions of a plurality of electrode fingers of the third IDT electrode are a first direction D+. In the third IDT electrode, a length of the electrode finger increases toward the first direction D+.

In the present preferred embodiment, a current caused by a secondary distorted current I₂ₑ flowing out from a second IDT electrode of the second acoustic wave resonator 21B and a second IDT electrode of the first acoustic wave resonator 1A can be canceled out. Further, a current caused by a secondary distorted current I₂ₑ flowing out from the second IDT electrode of the second acoustic wave resonator 21B and the third IDT electrode of the third acoustic wave resonator 1C can be canceled out. Thus, harmonic wave distortion can be effectively reduced or prevented.

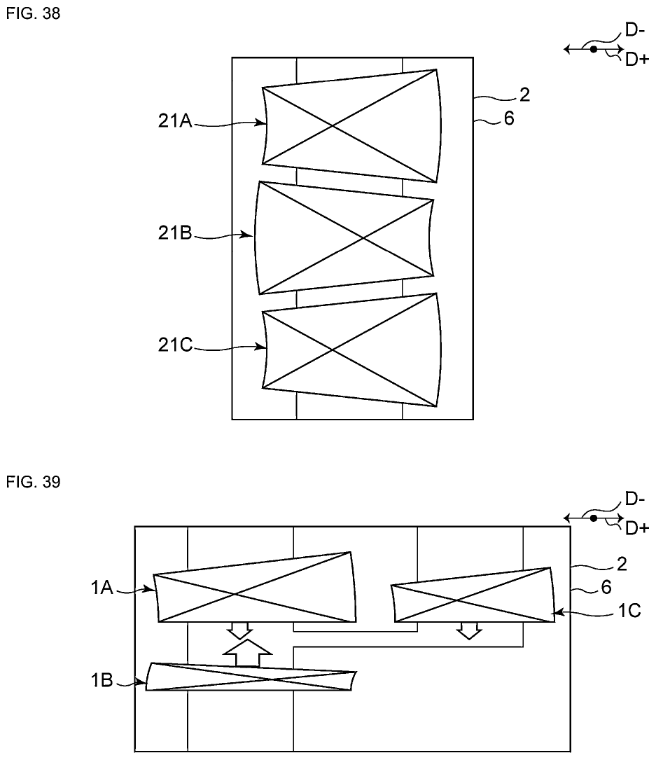

Note that, it is sufficient that the third acoustic wave resonator have a configuration similar to any configuration of the first acoustic wave resonators according to the present invention. For example, in a modification example of the ninth preferred embodiment illustrated in FIG. 38, a third acoustic wave resonator 21C is structured similarly to the first acoustic wave resonator 21A according to the second preferred embodiment. Thus, the third IDT electrode is structured similarly to the first IDT electrode according to the second preferred embodiment. The first acoustic wave resonator 21A according to the present modification example is also structured as in the second preferred embodiment. In this case, harmonic wave distortion can also be effectively reduced or prevented.

FIG. 39 is a schematic plan view illustrating a parallel arm resonator and a plurality of series arm resonators according to a tenth preferred embodiment. Arrows in FIG. 39 are indicators of a magnitude relationship of a magnitude of a current caused by a secondary distorted current I₂ₑ output from each IDT electrode. The same applies to other schematic plan views to be described later.

The present preferred embodiment is different from the eighth preferred embodiment in dispositions and configurations of a first acoustic wave resonator and a second acoustic wave resonator. The present preferred embodiment is different from the eighth preferred embodiment in that a third acoustic wave resonator is included. In other configurations than the above configuration, the acoustic wave device of the present preferred embodiment has a configuration similar to the configuration of the acoustic wave device of the eighth preferred embodiment. Note that, a circuit configuration according to the present preferred embodiment and the circuit configuration according to the eighth preferred embodiment are the same. Thus, the reference numerals used in the description of the eighth preferred embodiment are used in the description of the present preferred embodiment.

In the present preferred embodiment, a series arm resonator S2 illustrated in FIG. 32 is a first acoustic wave resonator 1A. A series arm resonator S3 is a second acoustic wave resonator 1B. The first acoustic wave resonator 1A and the second acoustic wave resonator 1B are structured as in the first preferred embodiment. A parallel arm resonator P2 is a third acoustic wave resonator 1C. The third acoustic wave resonator 1C is connected to both the first acoustic wave resonator 1A and the second acoustic wave resonator 1B without another acoustic wave resonator interposed therebetween. The third acoustic wave resonator 1C has a configuration similar to the configuration of the first acoustic wave resonator 1A according to the first preferred embodiment.

Outer side directions of a plurality of electrode fingers of a first IDT electrode in the first acoustic wave resonator and a third IDT electrode in the third acoustic wave resonator are a first direction D+. On the other hand, outer side directions of a plurality of electrode fingers of a second IDT electrode in the second acoustic wave resonator are a second direction D−. Thus, in the first IDT electrode, the second IDT electrode, and the third IDT electrode, a total number of IDT electrodes of which the outer side direction is the first direction D+ is larger than a total number of IDT electrodes of which the outer side direction is the second direction D−. Thus, a total number of IDT electrodes for which a negative sign current caused by a secondary distorted current I₂ₑ is output to a second busbar side is larger than a total number of IDT electrodes for which a positive sign current caused by a secondary distorted current I₂ₑ is output to a first busbar side.

However, in the present preferred embodiment, among the first acoustic wave resonator 1A, the second acoustic wave resonator 1B, and the third acoustic wave resonator 1C, an electrostatic capacitance of the second acoustic wave resonator 1B is the smallest. In a case where the electrostatic capacitance of the acoustic wave resonator is small, a voltage applied around one electrode finger is large. Thus, among the first IDT electrode, the second IDT electrode, and the third IDT electrode, a magnitude of a current caused by a secondary distorted current I₂ₑ output from the second IDT electrode is the largest. As a result, currents caused by secondary distorted currents I₂ₑ flowing out from the first IDT electrode, the second IDT electrode, and the third IDT electrode, can be more reliably canceled out. Thus, harmonic wave distortion can be more reliably reduced or prevented.

As described above, in the three acoustic wave resonators, harmonic wave distortion may be comprehensively reduced or prevented. Note that, it is sufficient that the total number of IDT electrodes of which the outer side direction is the first direction D+ be equal to or larger than the total number of IDT electrodes of which the outer side direction is the second direction D−.

In the present preferred embodiment, only one third acoustic wave resonator is provided. However, the configuration of the acoustic wave device may be a configuration in which a plurality of third acoustic wave resonators are provided. That is, in a preferred embodiment of the present invention, the plurality of IDT electrodes may include at least one third IDT electrode. In this case, it is sufficient that any third acoustic wave resonator be connected to both the first acoustic wave resonator and the second acoustic wave resonator without another acoustic wave resonator interposed therebetween.

In a case where the plurality of third IDT electrodes are provided, it is sufficient that outer side directions of the third IDT electrodes be one of the first direction D+ and the second direction D−. As a result, in the first IDT electrode, the second IDT electrode, and the at least one third IDT electrode, it is sufficient that the total number of IDT electrodes of which the outer side direction is the first direction D+ be set to be equal to or larger than the total number of IDT electrodes of which the outer side direction is the second direction D−. Then, among the first acoustic wave resonator, the second acoustic wave resonator, and the at least one third acoustic wave resonator, it is sufficient that the electrostatic capacitance of the second acoustic wave resonator be the smallest.

In the third IDT electrode in the third acoustic wave resonator 1C illustrated in FIG. 39, a length of the electrode finger increases toward the first direction D+. Note that, in a case where the plurality of third IDT electrodes are provided, in each of the third IDT electrodes, it is sufficient that a length of the electrode finger become longer toward one of the first direction D+ and the second direction D−. As a result, in the first IDT electrode, the second IDT electrode, and the at least one third IDT electrode, it is sufficient that a total number of IDT electrodes of which the electrode finger increases in length toward the first direction D+ be equal to or larger than a total number of IDT electrodes of which the electrode finger increases in length toward the second direction D−. Then, among the first acoustic wave resonator 1A, the second acoustic wave resonator 1B, and the at least one third acoustic wave resonator 1C, it is sufficient that the electrostatic capacitance of the second acoustic wave resonator 1B be the smallest. In this case, the harmonic wave distortion can also be more reliably reduced or prevented.

In the tenth preferred embodiment and the example illustrated above, a relationship between the number of pairs of electrode fingers is not particularly limited in the first IDT electrode, the second IDT electrode, and the third IDT electrode. However, it is preferable that each of the number of pairs of electrode fingers of the first IDT electrode, the second IDT electrode, and the third IDT electrode is equal to or larger than about 80% of the number of pairs of electrode fingers having the largest number of pairs of electrode fingers in the IDT electrode among the first IDT electrode, the second IDT electrode, and the third IDT electrode. In this case, harmonic wave distortion can be more reliably reduced or prevented.

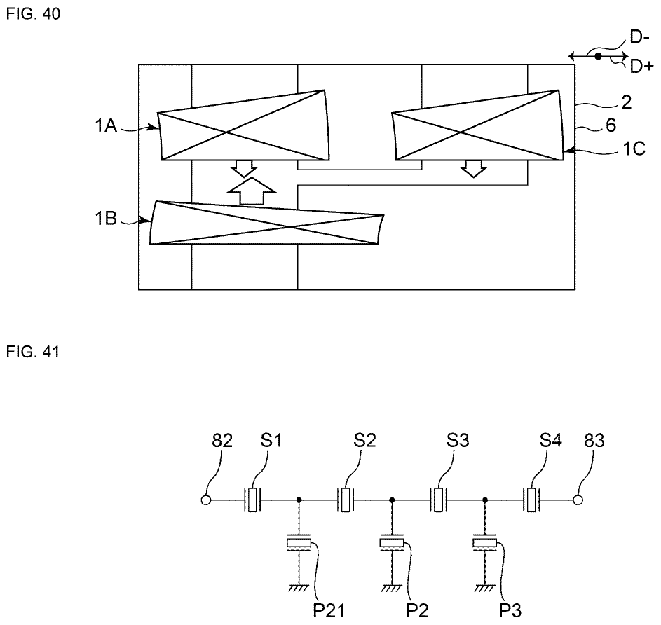

FIG. 40 is a schematic plan view illustrating a parallel arm resonator and a plurality of series arm resonators according to an eleventh preferred embodiment.

The present preferred embodiment is different from the tenth preferred embodiment in a relationship between electrostatic capacitances of a first acoustic wave resonator 1A, a second acoustic wave resonator 1B, and a third acoustic wave resonator 1C and in a relationship between the number of pairs of electrode fingers. In other configurations than the above configuration, the acoustic wave device of the present preferred embodiment has a configuration similar to the configuration of the acoustic wave device of the tenth preferred embodiment. Note that, a circuit configuration according to the present preferred embodiment is the same as the circuit configurations according to the eighth preferred embodiment and the tenth preferred embodiment. Thus, the reference numerals used in the description of the eighth preferred embodiment are used in the description of the present preferred embodiment.

A first acoustic wave resonator 1A includes a first IDT electrode. A second acoustic wave resonator 1B includes a second IDT electrode. A third acoustic wave resonator 1C includes a third IDT electrode. As in the tenth preferred embodiment, in the first IDT electrode, the second IDT electrode, and the third IDT electrode, a total number of IDT electrodes of which the outer side direction is a first direction D+ is larger than a total number of IDT electrodes of which the outer side direction is a second direction D−.

Then, in the present preferred embodiment, among the first IDT electrode, the second IDT electrode, and the third IDT electrode, the number of pairs of electrode fingers of the second IDT electrode is the largest. A current caused by a secondary distorted current I₂ₑ is output from each electrode finger. Thus, in a case where the number of pairs of electrode fingers of the IDT electrode is large, a magnitude of a current caused by a secondary distorted current I₂ₑ to be output is large. Thus, among the first IDT electrode, the second IDT electrode, and the third IDT electrode, a magnitude of a current caused by a secondary distorted current I₂ₑ output from the second IDT electrode is the largest. As a result, currents caused by secondary distorted currents I₂ₑ flowing out from the first IDT electrode, the second IDT electrode, and the third IDT electrode, can be more reliably canceled out. Thus, harmonic wave distortion can be more reliably reduced or prevented.

Note that, the configuration of the acoustic wave device may be a configuration in which the plurality of IDT electrodes include at least one third IDT electrode. In this case, it is sufficient that any third acoustic wave resonator 1C also be connected to both the first acoustic wave resonator 1A and the second acoustic wave resonator 1B without another acoustic wave resonator interposed therebetween.

In a case where the plurality of third IDT electrodes are provided, it is sufficient that outer side directions of the third IDT electrodes be one of the first direction D+ and the second direction D−. As a result, in the first IDT electrode, the second IDT electrode, and the at least one third IDT electrode, it is sufficient that the total number of IDT electrodes of which the outer side direction is the first direction D+ be set to be equal to or larger than the total number of IDT electrodes of which the outer side direction is the second direction D−. Then, among the first IDT electrode, the second IDT electrode, and the at least one third IDT electrode, it is sufficient that the number of pairs of electrode fingers of the second IDT electrode be the largest.

In the third IDT electrode in the third acoustic wave resonator 1C illustrated in FIG. 40, a length of the electrode finger increases toward the first direction D+. Note that, in a case where the plurality of third IDT electrodes are provided, in each of the third IDT electrodes, it is sufficient that a length of the electrode finger become longer toward one of the first direction D+ and the second direction D−. As a result, in the first IDT electrode, the second IDT electrode, and the at least one third IDT electrode, it is sufficient that a total number of IDT electrodes of which the electrode finger increases in length toward the first direction D+ be equal to or larger than a total number of IDT electrodes of which the electrode finger increases in length toward the second direction D−. Then, among the first IDT electrode, the second IDT electrode, and the at least one third IDT electrode, it is sufficient that the number of pairs of electrode fingers of the second IDT electrode be the largest. In this case, the harmonic wave distortion can also be more reliably reduced or prevented.

In the eleventh preferred embodiment and the example illustrated above, a relationship between the electrostatic capacitances is not particularly limited in the first acoustic wave resonator 1A, the second acoustic wave resonator 1B, and the third acoustic wave resonator 1C. However, it is preferable that each of the electrostatic capacitances of the first acoustic wave resonator 1A, the second acoustic wave resonator 1B, and the third acoustic wave resonator 1C is equal to or larger than about 80% of the electrostatic capacitance of the acoustic wave resonator having the largest electrostatic capacitance among the first acoustic wave resonator 1A, the second acoustic wave resonator 1B, and the third acoustic wave resonator 1C. In this case, harmonic wave distortion can be more reliably reduced or prevented.

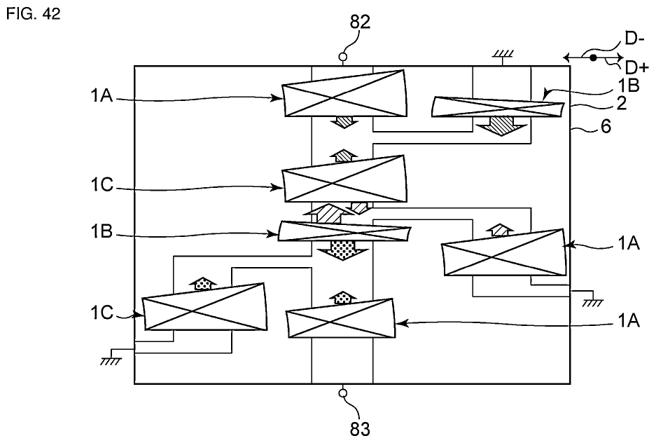

FIG. 41 is a circuit diagram of an acoustic wave device according to a twelfth preferred embodiment. FIG. 42 is a schematic plan view illustrating a plurality of parallel arm resonators and a plurality of series arm resonators according to the twelfth preferred embodiment.

As illustrated in FIGS. 41 and 42, the present preferred embodiment is different from the eighth preferred embodiment in a circuit configuration. In the description of the present preferred embodiment, the reference numerals used in the description of the eighth preferred embodiment are used to portions of the present preferred embodiment having the same circuit configuration as the eighth preferred embodiment. The circuit configuration of the present preferred embodiment is different from the eighth preferred embodiment only in that one parallel arm resonator P21 is connected between a connection point between a series arm resonator S1 and a series arm resonator S2 and a ground potential. The present preferred embodiment is also different from the eighth preferred embodiment in that all acoustic wave resonators are any one of a first acoustic wave resonator 1A, a second acoustic wave resonator 1B, and a third acoustic wave resonator 1C. In other configurations than the above configuration, the acoustic wave device of the present preferred embodiment has a configuration similar to the configuration of the acoustic wave device of the eighth preferred embodiment.

The series arm resonator S1 illustrated in FIG. 41 is the first acoustic wave resonator 1A illustrated in FIG. 42. The parallel arm resonator P21 is the second acoustic wave resonator 1B. The series arm resonator S2 is the third acoustic wave resonator 1C. A parallel arm resonator P2 is the first acoustic wave resonator 1A. A series arm resonator S3 is the second acoustic wave resonator 1B. A parallel arm resonator P3 is the third acoustic wave resonator 1C. A series arm resonator S4 is the first acoustic wave resonator 1A.

In the present preferred embodiment, three sets of acoustic wave resonator groups including the first acoustic wave resonator 1A, the second acoustic wave resonator 1B, and the third acoustic wave resonator 1C are disposed. Note that, a portion of the acoustic wave resonators overlaps in the three sets of acoustic wave resonator groups. More specifically, the first set among the three sets of acoustic wave resonator groups is the series arm resonator S1, the series arm resonator S2, and the parallel arm resonator P21. The second set is the series arm resonator S2, the series arm resonator S3, and the parallel arm resonator P2. The third set is the series arm resonator S3, the series arm resonator S4, and the parallel arm resonator P3.

In any of the three sets of acoustic wave resonator groups, the third acoustic wave resonator 1C is connected to both the first acoustic wave resonator 1A and the second acoustic wave resonator 1B without another acoustic wave resonator interposed therebetween. Then, a relationship between the outer side directions and a relationship between electrostatic capacitances in the first acoustic wave resonator 1A, the second acoustic wave resonator 1B, and the third acoustic wave resonator 1C are similar to the relationships in the eighth preferred embodiment.

Note that, arrows in FIG. 42 are depicted by hatching. The same hatched arrows indicate a magnitude relationship between magnitudes of currents caused by secondary distorted currents I₂ₑ output from the IDT electrodes in the same acoustic wave resonator group. As illustrated in FIG. 42, it can be seen that the currents are canceled out in each acoustic wave resonator group as in the eighth preferred embodiment. Thus, harmonic wave distortion can be reduced or prevented in each acoustic wave resonator group.

As described above, in the present preferred embodiment, harmonic wave distortion can be comprehensively reduced or prevented as the entire acoustic wave device as the filter device. Note that, a relationship between the number of pairs of electrode fingers in the first acoustic wave resonator 1A, the second acoustic wave resonator 1B, and the third acoustic wave resonator 1C of the three sets of acoustic wave resonator groups may be similar to the relationship in the ninth preferred embodiment. In this case, harmonic wave distortion can also be comprehensively reduced or prevented as the entire acoustic wave device.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric substrate including a piezoelectric layer; and
a plurality of IDT electrodes provided on the piezoelectric substrate and each including a plurality of electrode fingers; wherein
the plurality of IDT electrodes include a plurality of curved IDT electrodes in which shapes of the plurality of electrode fingers in plan view are curved shapes;
a direction in which a curved portion including a curved shape of an electrode finger in a curved IDT electrode is convex in directions in which the plurality of electrode fingers are arranged is an outer side direction of the curved portion;
the plurality of IDT electrodes include a first IDT electrode and a second IDT electrode, and both the first IDT electrode and the second IDT electrode are the curved IDT electrodes;
a plurality of acoustic wave resonators each including the IDT electrode are provided and include a first acoustic wave resonator including the first IDT electrode and a second acoustic wave resonator including the second IDT electrode; and
the first acoustic wave resonator and the second acoustic wave resonator are connected without another acoustic wave resonator interposed therebetween, and when one of the directions in which the plurality of electrode fingers are arranged is a first direction and a direction opposite to the first direction is a second direction in the first IDT electrode and the second IDT electrode, the outer side direction in the first IDT electrode is the first direction, and the outer side direction of the second IDT electrode is the second direction.

2. An acoustic wave device comprising:
a piezoelectric substrate including a piezoelectric layer; and
a plurality of IDT electrodes provided on the piezoelectric substrate and each including a plurality of electrode fingers;
wherein the plurality of IDT electrodes include a plurality of curved IDT electrodes in which shapes of the plurality of electrode fingers in plan view are curved shapes;
the plurality of IDT electrodes include a first IDT electrode and a second IDT electrode, and both the first IDT electrode and the second IDT electrode are the curved IDT electrodes;
a plurality of acoustic wave resonators each including the IDT electrode are provided and include a first acoustic wave resonator including the first IDT electrode and a second acoustic wave resonator including the second IDT electrode; and
the first acoustic wave resonator and the second acoustic wave resonator are connected without another acoustic wave resonator interposed therebetween, and when one of directions in which the plurality of electrode fingers are arranged is a first direction and a direction opposite to the first direction is a second direction in the first IDT electrode and the second IDT electrode, a length of an electrode finger increases toward the first direction in the first IDT electrode, and a length of an electrode finger increases toward the second direction in the second IDT electrode.

3. An acoustic wave device comprising:
a piezoelectric substrate including a piezoelectric layer; and
a plurality of IDT electrodes provided on the piezoelectric substrate and each including a plurality of electrode fingers; wherein
the plurality of IDT electrodes include a plurality of curved IDT electrodes in which shapes of the plurality of electrode fingers in plan view are curved shapes;
a direction in which a portion including a curved shape of an electrode finger in a curved IDT electrode is convex in directions in which the plurality of electrode fingers are arranged is an outer side direction of the portion including the curved shape;
the plurality of IDT electrodes include a first IDT electrode and a second IDT electrode, and both the first IDT electrode and the second IDT electrode are the curved IDT electrodes;
when one of the directions in which the plurality of electrode fingers are arranged is a first direction and a direction opposite to the first direction is a second direction in the first IDT electrode and the second IDT electrode, the first IDT electrode includes at least one first region where the outer side direction is the first direction and at least one second region where the outer side direction is the second direction, and the second IDT electrode includes at least a region where the outer side direction is the second direction;
a plurality of acoustic wave resonators each including the IDT electrode are provided and include a first acoustic wave resonator including the first IDT electrode and a second acoustic wave resonator including the second IDT electrode; and
the first acoustic wave resonator and the second acoustic wave resonator are connected without another acoustic wave resonator interposed therebetween, a total area of the first region is larger than a total area of the second region in the first IDT electrode, and a total area of the region where the outer side direction is the second direction is larger than a total area of the region where the outer side direction is the first direction in the second IDT electrode.

4. An acoustic wave device comprising:
a piezoelectric substrate including a piezoelectric layer; and
a plurality of IDT electrodes provided on the piezoelectric substrate and each including a plurality of electrode fingers; wherein
the plurality of IDT electrodes include a plurality of curved IDT electrodes in which shapes of the plurality of electrode fingers in plan view are curved shapes;
a direction in which a curved portion including a curved shape of an electrode finger in a curved IDT electrode is convex in directions in which the plurality of electrode fingers are arranged is an outer side direction of the curved portion;
the plurality of IDT electrodes include a first IDT electrode and a second IDT electrode, and both the first IDT electrode and the second IDT electrode are the curved IDT electrodes;
when one of the directions in which the plurality of electrode fingers are arranged is a first direction and a direction opposite to the first direction is a second direction in the first IDT electrode and the second IDT electrode, the first IDT electrode includes at least one first region where the outer side direction is the first direction and at least one second region where the outer side direction is the second direction, and the second IDT electrode includes at least a region where the outer side direction is the second direction;
a plurality of acoustic wave resonators each including the IDT electrode are provided and include a first acoustic wave resonator including the first IDT electrode and a second acoustic wave resonator including the second IDT electrode; and
the first acoustic wave resonator and the second acoustic wave resonator are connected without another acoustic wave resonator interposed therebetween, a total area of the first region is larger than a total area of the second region in the first IDT electrode, a length of an electrode finger increases toward one of the first direction and the second direction in the first IDT electrode, and a length of an electrode finger increases toward another of the first direction and the second direction in the second IDT electrode.

5. The acoustic wave device according to claim 1, wherein
the plurality of acoustic wave resonators include at least one third acoustic wave resonator connected to both the first acoustic wave resonator and the second acoustic wave resonator without another acoustic wave resonator interposed therebetween;
the plurality of IDT electrodes include at least one third IDT electrode, the at least one third acoustic wave resonator includes the at least one third IDT electrode, the at least one third IDT electrode is the curved IDT electrode, and the outer side direction in the third IDT electrode is one of the first direction and the second direction;
in the first IDT electrode, the second IDT electrode, and the at least one third IDT electrode, a total number of the IDT electrodes of which the outer side direction is the first direction is equal to or larger than a total number of the IDT electrodes of which the outer side direction is the second direction; and
among the first acoustic wave resonator, the second acoustic wave resonator, and the at least one third acoustic wave resonator, an electrostatic capacitance of the second acoustic wave resonator is smallest.

6. The acoustic wave device according to claim 1, wherein
the plurality of acoustic wave resonators include at least one third acoustic wave resonator connected to both the first acoustic wave resonator and the second acoustic wave resonator without another acoustic wave resonator interposed therebetween;
the plurality of IDT electrodes include at least one third IDT electrode, the at least one third acoustic wave resonator includes the at least one third IDT electrode, the at least one third IDT electrode is the curved IDT electrode, and the outer side direction in the at least one third IDT electrode is one of the first direction and the second direction;
in the first IDT electrode, the second IDT electrode, and the at least one third IDT electrode, a total number of the IDT electrodes of which the outer side direction is the first direction is equal to or larger than a total number of the IDT electrodes of which the outer side direction is the second direction; and
among the first IDT electrode, the second IDT electrode, and the at least one third IDT electrode, a number of pairs of the plurality of electrode fingers of the second IDT electrode is largest.

7. The acoustic wave device according to claim 2, wherein
a direction in which a curved portion of an electrode finger in a curved IDT electrode is convex in the directions in which the plurality of electrode fingers are arranged is an outer side direction of the curved portion; and
the outer side direction in the first IDT electrode is one of the first direction and the second direction, and the outer side direction in the second IDT electrode is another of the first direction and the second direction.

8. The acoustic wave device according to claim 2, wherein
the plurality of acoustic wave resonators include at least one third acoustic wave resonator connected to both the first acoustic wave resonator and the second acoustic wave resonator without another acoustic wave resonator interposed therebetween;
the plurality of IDT electrodes include at least one third IDT electrode, the at least one third acoustic wave resonator includes the at least one third IDT electrode, the at least one third IDT electrode is the curved IDT electrode, and a length of an electrode finger increases in length toward one of the first direction and the second direction in the at least one third IDT electrode;
in the first IDT electrode, the second IDT electrode, and the at least one third IDT electrode, a total number of the IDT electrodes in which the electrode finger increases in length toward the first direction is equal to or larger than a total number of the IDT electrodes of which the electrode finger increases in length toward the second direction;
among the first acoustic wave resonator, the second acoustic wave resonator, and the at least one third acoustic wave resonator, an electrostatic capacitance of the second acoustic wave resonator is smallest.

9. The acoustic wave device according to claim 2, wherein
the plurality of acoustic wave resonators include at least one third acoustic wave resonator connected to both the first acoustic wave resonator and the second acoustic wave resonator without another acoustic wave resonator interposed therebetween;
the plurality of IDT electrodes include at least one third IDT electrode, the at least one third acoustic wave resonator includes the at least one third IDT electrode, the at least one third IDT electrode is the curved IDT electrode, and a length of an electrode finger increases in length toward one of the first direction and the second direction in the at least one third IDT electrode;
in the first IDT electrode, the second IDT electrode, and the at least one third IDT electrode, a total number of the IDT electrodes in which the electrode finger increases in length toward the first direction is equal to or larger than a total number of the IDT electrodes of which the electrode finger increases in length toward the second direction; and
among the first IDT electrode, the second IDT electrode, and the at least one third IDT electrode, a number of pairs of the plurality of electrode fingers of the second IDT electrode is largest.

10. The acoustic wave device according to claim 1, wherein a shape of the first IDT electrode and a shape of the second IDT electrode are in a line symmetrical relationship.

11. The acoustic wave device according to claim 2, wherein a shape of the first IDT electrode and a shape of the second IDT electrode are in a line symmetrical relationship.

12. The acoustic wave device according to claim 1, wherein
shapes of the first IDT electrode and the second IDT electrode are the same; and
a position of the second IDT electrode is rotated by 180° relative to the first IDT electrode.

13. The acoustic wave device according to claim 2, wherein
shapes of the first IDT electrode and the second IDT electrode are the same; and
a position of the second IDT electrode is rotated by 180° relative to the first IDT electrode.

14. The acoustic wave device according to claim 1, wherein a difference between an electrostatic capacitance of the first acoustic wave resonator and an electrostatic capacitance of the second acoustic wave resonator is equal to or less than about 0.35 pF.

15. The acoustic wave device according to claim 2, wherein a difference between an electrostatic capacitance of the first acoustic wave resonator and an electrostatic capacitance of the second acoustic wave resonator is equal to or less than about 0.35 pF.

16. The acoustic wave device according to claim 1, wherein
an X-propagation piezoelectric material is the same as a material of the piezoelectric layer; and
the first direction is one of a positive direction and a negative direction in an X-propagation direction, and the second direction is another of the positive direction and the negative direction in the X-propagation direction.

17. The acoustic wave device according to claim 1, wherein
the piezoelectric substrate includes a support substrate; and
the piezoelectric layer is provided on the support substrate.

18. The acoustic wave device according to claim 17, wherein the piezoelectric substrate includes an intermediate layer between the support substrate and the piezoelectric layer.

19. The acoustic wave device according to claim 17, wherein the piezoelectric substrate includes a hollow portion, and a portion of the support substrate and a portion of the piezoelectric layer face each other with the hollow portion interposed therebetween.

20. The acoustic wave device according to claim 1, wherein the piezoelectric substrate includes only the piezoelectric layer.
